(19) United States
(12) Patent Application Publication
(10) Pub. No.: US 2026/0334309 A1
(43) Pub. Date: Oct. 22, 2026

(54) SEMICONDUCTOR PACKAGE ASSEMBLY

(71) Applicant: MEDIATEK INC., Hsinchu City (TW)

(72) Inventors: Chuan-An CHENG, Hsinchu City (TW); Ting-Li YANG, Hsinchu City (TW); Cheng-Lin HUANG, Hsinchu City (TW)

(21) Appl. No.: 19/316,396

(22) Filed: Sep. 2, 2025

Related U.S. Application Data
(60) Provisional application No. 63/693,763, filed on Sep. 12, 2024.

(51) Int. Cl. H01L 23/00; H01L 23/31; H01L 23/34; H01L 23/48; H01L 23/538; H01L 25/16

(52) U.S. Cl. CPC H10W 90/00; H10W 20/20; H10W 40/00; H10W 70/60; H10W 70/611; H10W 74/131; H10W 90/792

(57) ABSTRACT

A semiconductor package assembly is provided. The semiconductor package assembly includes a substrate, a first chiplet structure, a memory structure, a first carrier structure, and a second carrier structure. The first chiplet structure is disposed on the substrate. The first chiplet structure has a first height. The memory structure is disposed on the substrate and beside the first chiplet. The memory structure has a second height that is different from the first height in a direction that is substantially perpendicular to a top surface of the substrate. The first carrier structure is bonded to the first chiplet structure. The second carrier structure is bonded to the memory structure and beside the first carrier structure. Top surfaces of the first carrier structure and second carrier structure are aligned with each other.

### CROSS REFERENCE TO RELATED APPLICATIONS

This application claims the benefit of U.S. provisional application No. 63/693,763, filed Sep. 12, 2024, the entirety of which is incorporated by reference herein.

### TECHNICAL FIELD

The present disclosure relates to a semiconductor package assembly, and, in particular, it relates to a co-packaging assembly.

### BACKGROUND

In order to ensure the continued miniaturization and multi-functionality of electronic products and communication devices, it is desired that semiconductor packages be small in size, support multi-pin connection, operate at high speeds, and have high functionality, especially in applications such as artificial intelligence (AI), high-performance computing (HPC), and data centers. This puts pressure on semiconductor package fabricators to integrate multiple dies within a single package, thereby minimizing the track lengths between different semiconductor chips and improving electrical performance. However, semiconductor chips inevitably generate heat during operation. Thus, how to dissipate the heat from semiconductor chips has become a crucial task for the industry.

Thus, a novel semiconductor package assembly is needed.

### BRIEF SUMMARY

An embodiment of the present disclosure provides a semiconductor package assembly. The semiconductor package assembly includes a substrate, a first chiplet structure, a memory structure, a first carrier structure, and a second carrier structure. The first chiplet structure is disposed on the substrate. The first chiplet structure has a first height. The memory structure is disposed on the substrate and beside the first chiplet. The memory structure has a second height that is different from the first height in a direction that is substantially perpendicular to a top surface of the substrate. The first carrier structure is bonded to the first chiplet structure. The second carrier structure is bonded to the memory structure and beside the first carrier structure. Top surfaces of the first carrier structure and second carrier structure are aligned with each other.

An embodiment of the present disclosure provides a semiconductor package assembly. The semiconductor package assembly includes a substrate, a first chiplet structure, a memory structure, a first carrier structure, and a second carrier structure. The first chiplet structure is disposed on the substrate. The first chiplet structure has a first height. The memory structure is disposed on the substrate and beside the first chiplet. The memory structure has a second height that is different from the first height in a direction that is substantially perpendicular to a top surface of the substrate. The first carrier structure is bonded to the first chiplet structure. The first carrier structure has a third height. The second carrier structure is bonded to the memory structure and beside the first carrier structure. The second carrier structure has a fourth height. The sum of the first height and the third height is equal to the sum of the second height and the fourth height.

### BRIEF DESCRIPTION OF THE DRAWINGS

The present disclosure can be more fully understood by reading the subsequent detailed description and examples with references made to the accompanying drawings, wherein:

FIG. 1A is a cross-sectional view of a semiconductor package assembly in accordance with some embodiments of the disclosure;

FIG. 1B is a cross-sectional view of a semiconductor package assembly in accordance with some embodiments of the disclosure;

FIG. 1C is a cross-sectional view of a semiconductor package assembly in accordance with some embodiments of the disclosure;

FIG. 1D is a cross-sectional view of a semiconductor package assembly in accordance with some embodiments of the disclosure;

FIGS. 2A, 2B, 3A, 3B, 4A, 4B, 5A, 5B, 6A, 6B, 7A, and 7B are cross-sectional views of a carrier structure and a chiplet structure of a semiconductor package assembly in accordance with some embodiments of the disclosure; and

FIGS. 8, 9, 10, 11, 12 and 13 are cross-sectional views of a carrier structure and a memory structure of a semiconductor package assembly in accordance with some embodiments of the disclosure.

### DETAILED DESCRIPTION

The following description is made for the purpose of illustrating the general principles of the disclosure and should not be taken in a limiting sense. The scope of the disclosure is best determined by reference to the appended claims.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

In recent years, an advanced co-package platform for co-packaged high performance computing (HPC) application specific integrated circuit (ASICs) and high bandwidth memories (HBMs) has been developed. The HPC ASICs and HBM co-package uses a bridge die to electrically connect multiple active semiconductor dies, such as a logic die and one or more memory dies, disposed side-by-side on a substrate. However, the differences between the heights of the HPC ASICs and HBM will lead to non-uniform thermal interface material (TIM) coverage and thermal reliability concern in the co-package platform. Thus, a novel semiconductor package assembly has an improve thermal dissipation is desirable.

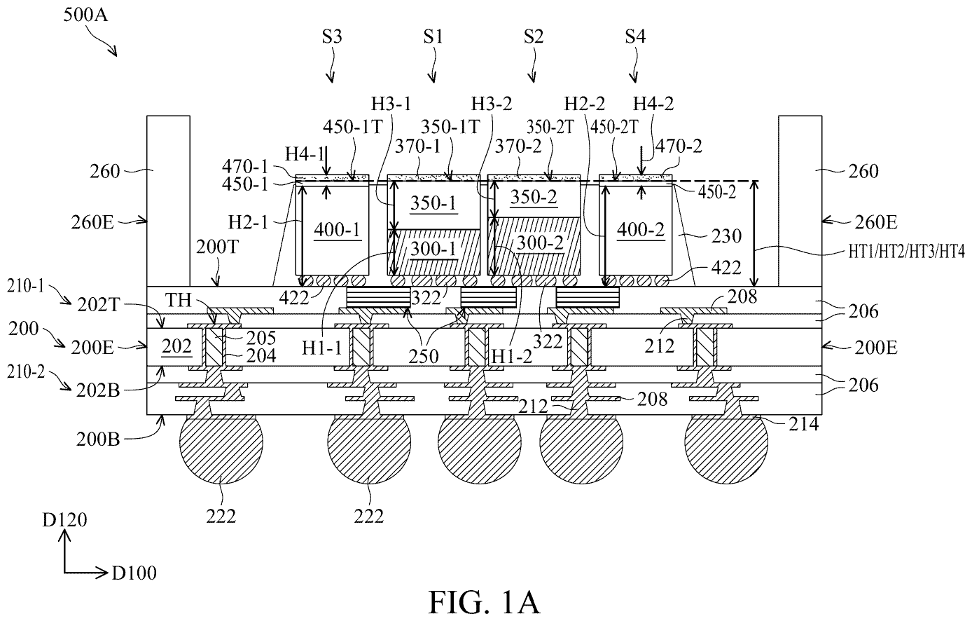

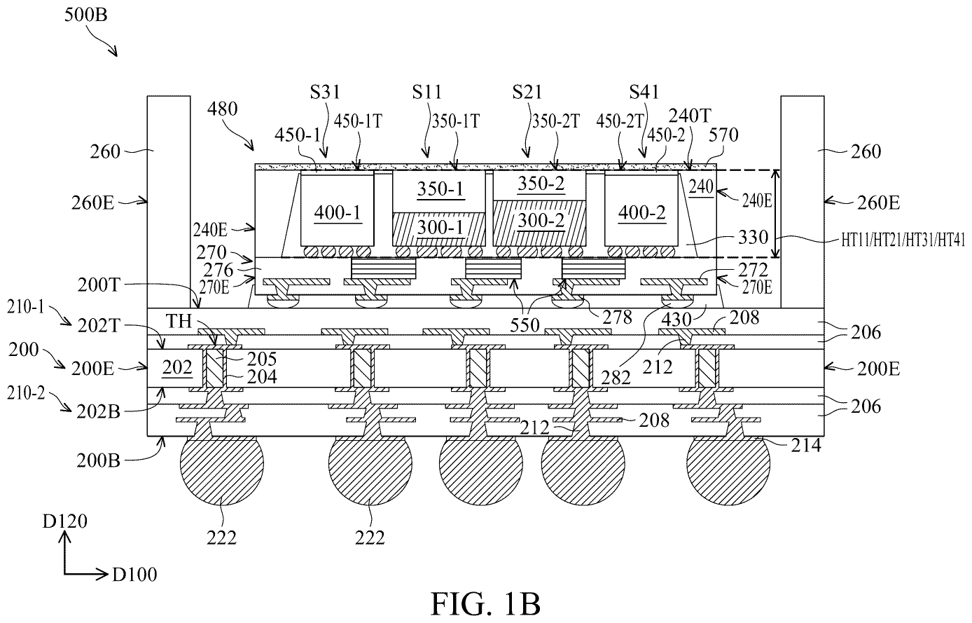

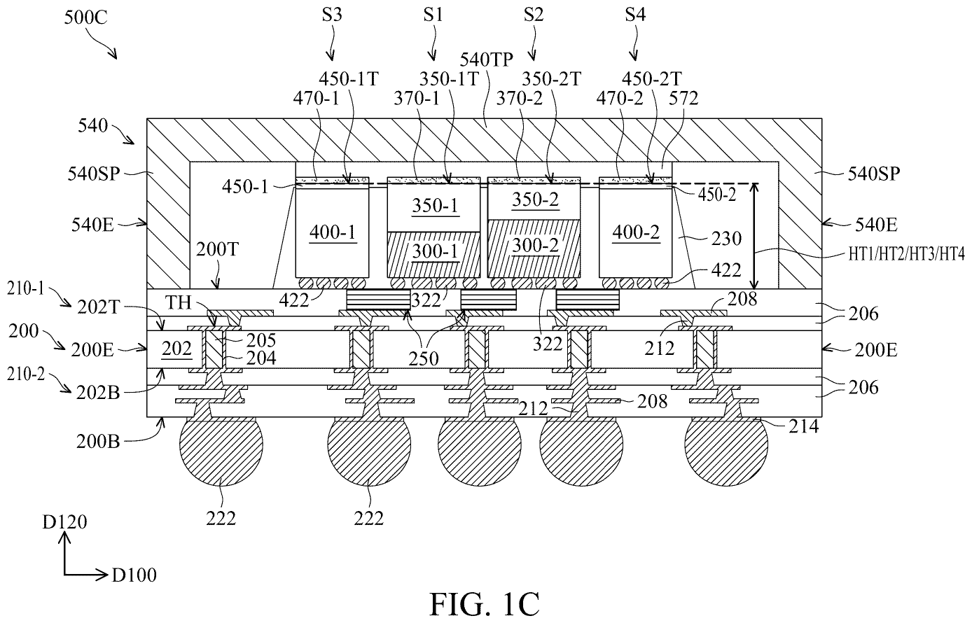

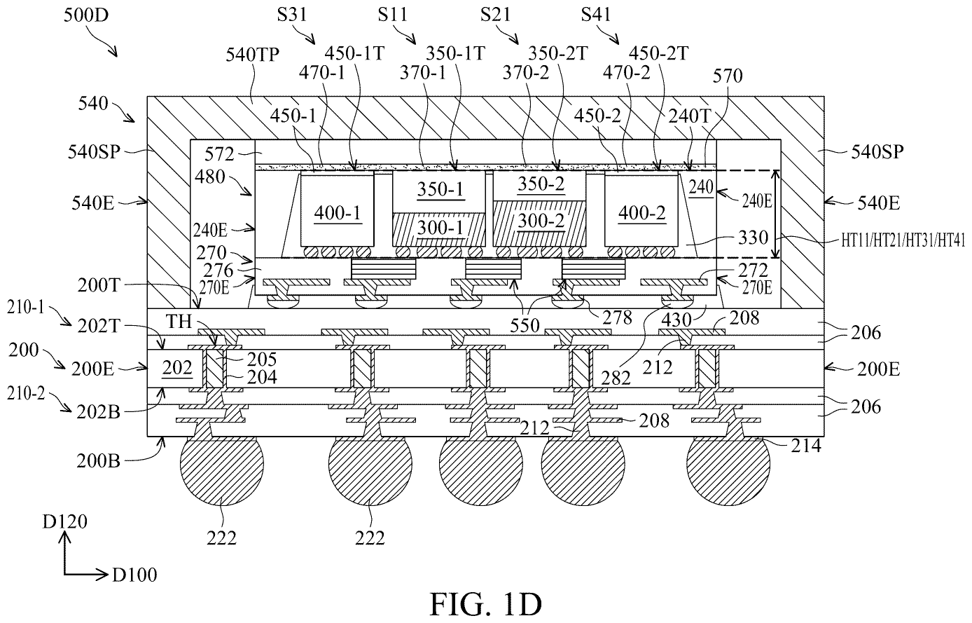

FIG. 1A is a cross-sectional view of a semiconductor package assembly 500A in accordance with some embodiments of the disclosure. The semiconductor package assembly 500A can be used to form a package requiring high-power operation, such as flip chip ball grid array (FCBGA), land grid array (LGA), a fan-out semiconductor package, a two-dimensional (2D) semiconductor package, a 2.5D semiconductor package, a three-dimensional (3D) semiconductor package, a 3.5D semiconductor package, or another suitable package. As shown in FIG. 1A, in some embodiments, the semiconductor package assembly 500A includes a substrate 200, a chiplet structure 300-1 (including chiplet structures 300-1A, 300-1B, 300-1C, 300-1D, 300-1E, 300-1F, 300-1G, 300-1H and, 300-1I in the following figures), a chiplet structure 300-2 (including chiplet structures 300-2A, 300-2B, 300-2C, 300-2D, 300-2E, 300-2F, 300-2G, 300-2H and, 300-2I in the following figures), a memory structure 400-1 (including memory structures 400-1A, 400-1B, 400-1C, 400-1D, 400-1E, 400-1F, 400-1G, 400-1H and, 400-1I in the following figures), a memory structure 400-2 (including memory structures 400-2A, 400-2B, 400-2C, 400-2D, 400-2E, 400-2F, 400-2G, 400-2H and, 400-2I in the following figures), a carrier structure 350-1 (including carrier structures 350-1A, 350-1B, 350-1C, 350-1D, 350-1E, 350-1F, 350-1G, 350-1H and, 350-1I in the following figures), and a carrier structure 350-2 (including carrier structures 350-2A, 350-2B, 350-2C, 350-2D, 350-2E, 350-2F, 350-2G, 350-2H and, 350-2I in the following figures). In FIG. 1A and the following figures, direction D100 is defined as horizontal directions (also regarded as the extending directions of conductive layers and/or conductive traces), and direction D120 is defined as a vertical direction (also regarded as the extending direction of the through via and/or vias).

As shown in FIG. 1A, the substrate 200 may include a multi-layered package substrate (e.g., a flip-chip ball grid array (FCBGA) substrate). The substrate 200 may provide mechanical support and electrical connections between integrated circuit (IC) chips and conductive bumps attached to the top and bottom surfaces of the substrate 200. The substrate 200 may have various types including, for example, a core substrate or a coreless substrate. The core substrate includes thin core, thick core (e.g., laminate BT (bismaleimide-triazine resin) or FR-4 type fibrous board material), and laminate core. Alternatively, the cored package substrates, for example, can be built up layer by layer around a central core, with layers of conductive material (usually copper) separated by layers of insulating dielectric, with interlayer connections being formed with through holes or vias (microvias).

In some embodiment as shown in FIG. 1A, the substrate 200 includes a core 202 and redistribution layers (RDLs) 210-1 and 210-2. The core 202 has a top surface 202T and a bottom surface 202B. In some embodiments, the core 202 may be formed of an organic material, a glass material, a ceramic material, a semiconductor material, the like, or a combination thereof. The organic material may include polypropylene, prepreg (PP), fiberglass resin (e.g., FR-4), bismaleimide triazine (BT) resin, the like, or a combination thereof. The semiconductor material may include silicon, germanium, or a compound material, including silicon germanium, silicon carbide, gallium arsenic, silicon germanium carbide, the like, or a combination thereof. The redistribution layers 210-1 and 210-2 are disposed on the top surface 202T and the bottom surface 202B of the core 202, respectively. In some embodiments, each of the redistribution layers 210-1 and 210-2 includes conductive layers 208, vias 212 disposed in one or more dielectric layers 206, and conductive pads 214.

In some embodiments, the dielectric layers 206 of the redistribution layers 210-1 and 210-2 are symmetrically disposed the top surface 202T and the bottom surface 202B of the core 202. For example, the number of dielectric layers 206 of the redistribution layer 210-1 is the same as the number of dielectric layers 206 of the redistribution layers 210-2. In some embodiments, the dielectric layers 206 may be formed of organic polymer, including polyimide (PI), polybenzoxazole (PBO), benzocyclobutene (BCB), epoxy, Ajinomoto build-up film (ABF), Bismaleimide-Triazine (BT resin), another suitable organic dielectric material, or a combination thereof, but it is not limited thereto. Alternatively, the dielectric layers 206 may be formed of silicon oxide, silicon nitride, silicon oxynitride, the like, or a combination thereof. In some embodiments, the dielectric layers 206 may be formed by a lamination process, a spin coating process, a chemical vapor deposition (CVD) process, or another applicable process. In accordance with some embodiment, the dielectric layers 206 may be patterned through one or more photolithography processes and/or etching processes.

It should be noted that the number of vias 212, the number of conductive layers 208 and the number of dielectric layers 206 of the redistribution layers 210-1 and 210-2 shown in FIG. 1A are only an example and is not a limitation to the present disclosure.

As shown in FIG. 1A, the substrate 200 has separated holes TH (or through holes TH) embedded it. In some embodiments, the holes TH are formed passing through the core 202 embedded it. In some embodiments, the holes TH are formed by a drilling process (e.g., mechanical drilling).

The conductive material 204 is disposed in the hole TH. In some embodiments, as shown in FIG. 1A, the conductive material 204 may be formed as a thin conductive layer lining inner walls of the hole TH. The conductive material 204 in the hole TH may have a hollow pillar shape. In some embodiments, the conductive material 204 include copper or nickel-copper and are formed by a plating process, such as chemical plating, electroplating or electro-less plating. For example, the conductive material 204 may also be called a plated through hole (PTHs) 204.

As shown in FIG. 1A, the substrate 200 of the semiconductor package assembly 500A further includes a non-conductive material 205 filling the remaining space of the hole TH and surrounded by the conductive material 204. In some embodiments, the non-conductive material 205 includes epoxy resin, such as an ink.

The conductive layers 208 are formed within the dielectric layers 206 at different levels. Some of the conductive traces 208 are formed directly on the top surface 202T and the bottom surface 202B of the core 202, respectively. In some embodiments, the conductive layers 208 may fully cover the holes TH, the conductive material 204 lining the inner walls of the holes TH and the non-conductive material 205 filling the holes TH. In addition, the conductive layers 208 may be connected (coupled) to the conductive material 204 lining the inner wall walls of the holes TH.

In some embodiments, the conductive layer 208 at each of levels of the redistribution layers 210-1 and 210-2 may include a set of conductive traces (not shown) or conductive planes (also called ground planes) (not shown). In some embodiments, the conductive traces may include power trace segments, signal trace segments or ground trace segments, which are used for the input/output (I/O) connections of the chiplet structures 300-1, 300-2 and the memory structures 400-1, 400-2.

As shown in FIG. 1A, the vias 212 disposed in the dielectric layers 206 of the redistribution layers 210-1 and 210-2. The vias 212 may be formed passing through the dielectric layers 206 of the redistribution layers 210-1 and 210-2 to be coupled to different levels of the conductive layers 208. In some embodiments, the vias 212 may be formed by laser-drilling and a subsequent deposition process.

The conductive pads 214 are exposed to openings of solder mask layers (not shown) disposed close to the top surface 200T and the bottom surface 200B of the substrate 200. The conductive pads 214 are coupled to different terminals of the conductive traces. The conductive pads 214 close to the top surface 200T of the substrate 200 are used for the chiplet structures 300-1, 300-2 and the memory structures 400-1, 400-2 mounted directly on them.

In some embodiments, the conductive layers 208, the vias 212 and the conductive pads 214 include a conductive material, such as metals including copper, gold, silver, or other applicable metals. For example, the conductive layers 208, the vias 212 and the conductive pads 214 may be formed of copper.

In some embodiments, the semiconductor package assembly 500A uses a chiplet architecture to split a large, single semiconductor die into multiple smaller functional semiconductor dies (called chiplets) fabricated in different technology nodes. Each chiplet may have improved device performance and fabrication yields. In addition, the semiconductor package assembly 500A may have a reduced fabrication cost. As shown in FIG. 1A, the semiconductor package assembly 500A includes at least two chiplet structures 300-1 and 300-2 arranged side-by-side in the direction D100. In some embodiments, the chiplet structure 300-1 and the chiplet structure 300-2 are mounted on top surface 200T of the substrate 200 by a bonding process using conductive structures 322 of the chiplet structure 300-1 and the chiplet structure 300-2. The chiplet structure 300-1 and the chiplet structure 300-2 are coupled to the redistribution layer 210-1 of the substrate 200. In some embodiments, the conductive structures 322 include a conductive ball structure such as a copper ball, a conductive bump structure such as a copper bump or a solder bump structure, or a conductive pillar structure such as a copper pillar structure. For example, the conductive structures 322 may be microbumps, controlled collapse chip connection (C4) bumps, solder balls, ball grid array (BGA) balls, another suitable conductive connector, or a combination thereof.

In some embodiments, each of the chiplet structure 300-1 and the chiplet structure 300-2 includes one or more semiconductor dies and the conductive structures 322. Each of the chiplet structure 300-1 and the chiplet structure 300-2 independently includes one or more system-on-chip (SoC) dies, system-on-integrated-circuits (SoIC) dies, logic devices, memory devices, radio frequency (RF) devices, the like, or any combination thereof. For example, the chiplet structure 300-1 and the chiplet structure 300-2 may each independently include one or more micro control unit (MCU) dies, microprocessor unit (MPU) dies, power management integrated circuit (PMIC) dies, radio frequency front end (RFFE) dies, a global positioning system (GPS) devices, central processing unit (CPU) dies, graphics processing unit (GPU) dies, input-output (IO) dies, a dynamic random access memory (DRAM) IP cores, application processor (AP) dies, application specific integrated circuit (ASIC) dies, the like, or any combination thereof. In this embodiments, the chiplet structure 300-1 and the chiplet structure 300-2 may include one or more ASIC dies. In some embodiments, the chiplet structure 300-1 and the chiplet structure 300-2 have different functions.

The chiplet structure 300-1 and the chiplet structure 300-2 may be fabricated in different technology nodes. In some embodiments, the chiplet structure 300-1 has a first critical dimension (CD) and the chiplet structure 300-2 has a second critical dimension different from the first critical dimension in order to provide different functionalities with a reduced cost. For example, the first critical dimension is narrower than the second critical dimension or vice versa. When the chiplet structure 300-1 or the chiplet structure 300-2 includes multiple semiconductor dies, the semiconductor dies in the same chiplet structure 300-1 or the chiplet structure 300-2 may have different critical dimensions. Therefore, the chiplet structure 300-1 and the chiplet structure 300-2 may respectively arrange various interfaces to fulfill the requirements of internal and external signal transmission of the semiconductor package assembly 500A.

In the direction D120, the chiplet structure 300-1 has a height H1-1 and the chiplet structure 300-2 has a height H1-2. In some embodiments, the height H1-1 is the same as or different from the height H1-2. For example, as shown in FIG. 1A, the height H1-1 of the chiplet structure 300-1 may be lower than the height H1-2 of the chiplet structure 300-2. It is noted that the relationship between the heights H1-1 and H1-2 is not limited to the disclosed embodiment.

The memory structures 400-1 and 400-2 are disposed on the top surface 200T of the substrate 200 and beside the chiplet structures 300-1 and 300-2. In some embodiments, the memory structures 400-1 and 400-2 are mounted on top surface 200T of the substrate 200 by a bonding process using conductive structures 422 of the memory structures 400-1 and 400-2. The memory structures 400-1 and 400-2 are coupled to the redistribution layer 210-1 of the substrate 200 via the conductive pads 214 close to the top surface (the top surface 200T) the RDL structure 210-1. In some embodiments, the conductive structures 422 may have a structure and arrangement that are the same or similar to the conductive structures 322.

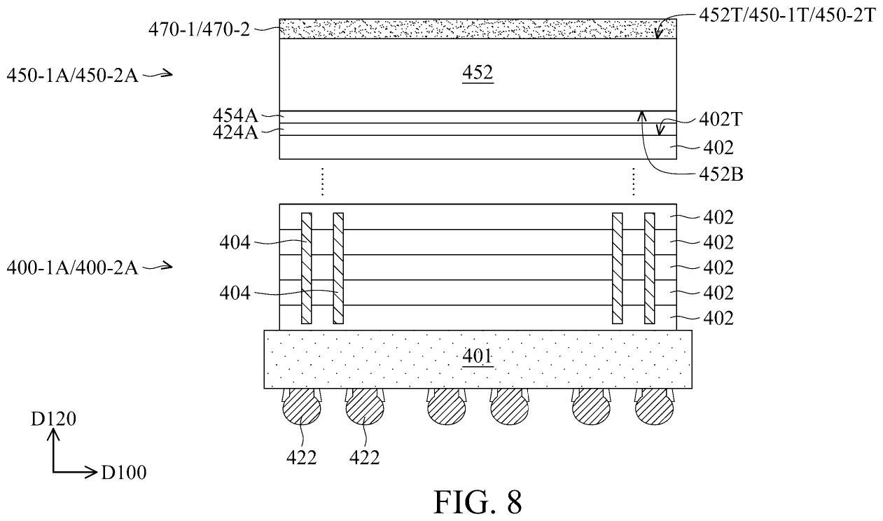

In some embodiments, each of the memory structures 400-1 and 400-2 may include a base die 401, memory dies 402 (FIGS. 8-13) and the conductive structures 422. The memory dies 402 stacked on each other and mounted on the base die 401 in the direction D120. The base die 401 is coupled between the memory dies 402 and the conductive structures 422. In some embodiments, each of the memory structures 400-1 and 400-2 may be a high-bandwidth memory (HBM). The base die 401 may include a dynamic random access memory (DRAM) controller die. In addition, each of memory dies 402 may be a dynamic random-access memory (DRAM) die. In accordance with some embodiments, the memory dies 402 may be hybrid bonded each other and interconnected through conductive vias 404. For example, each of the memory dies 402 may include one or more conductive vias 404. The conductive vias 404 may be through-silicon vias (TSVs). In accordance with some embodiments, the conductive via 404 may be formed of metal, such as copper, tungsten, tantalum, titanium, another suitable conductive material, an alloy thereof, or a combination thereof, but it is not limited thereto. In accordance with some embodiments, the conductive via 404 may be formed by a plating process, a chemical vapor deposition (CVD) process, a physical vapor deposition (PVD) process, or another applicable process.

In the direction D120, the memory structure 400-1 has a height H2-1 and the memory structures 400-2 has a height H2-2. In some embodiments, the height H2-1 is the same as or different from the height H2-2. For example, as shown in FIG. 1A, the height H2-1 of memory structures 400-1 may be the same as than the height H2-2 of the memory structures 400-2. In some embodiments, the height H2-1 of memory structures 400-1 may be different from the height H1-1 of the chiplet structure 300-1 and the height H1-2 of the chiplet structure 300-2. The height H2-2 of memory structures 400-2 may be different from the height H1-1 of the chiplet structure 300-1 and the height H1-2 of the chiplet structure 300-2. For example, the height H2-1 and the height H2-2 may be higher than the height H1-1 and the height H1-2. It is noted that the relationship between the heights H2-1 and H2-2 is not limited to the disclosed embodiment.

In some embodiments, the semiconductor package assembly 500A further includes conductive structures 222 disposed on the bottom surface 200B of the substrate 200 and opposite the chiplet structures 300-1, 300-2 and the memory structures 400-1, 400-2. The conductive structures 222 are in contact with the conductive pads 214 of the redistribution layer 210-2 of the substrate 200. Therefore, the substrate 200 is electrically connected to the external electronic component via the conductive structures 222. In accordance with some embodiments, the external electronic component may include a printed circuit board (PCB), a chip, a control component or another electronic component, but it is not limited thereto. In some embodiments, the conductive structures 222 include a conductive ball structure such as a copper ball, a conductive bump structure such as a copper bump or a solder bump structure, or a conductive pillar structure such as a copper pillar structure.

In some embodiments, the semiconductor package assembly 500A further includes one or more bridge structure 250 embedded in the substrate 200. The bridge structure 250 may be coupled between the chiplet structure 300-1 and the chiplet structure 300-2, between the chiplet structure 300-1 and the memory structure 400-1, and between chiplet structure 300-2 and the memory structure 400-2. In some embodiments, the bridge structure 250 may be disposed in a recess (not shown) formed in the upper portion of the dielectric layers 206 of the redistribution layer 210-1 of the substrate 200. The bridge structures 250 may overlap the chiplet structures 300-1, 300-2 and the memory structures 400-1, 400-2 in the direction D120. For example, the bridge structure 250 may vertically overlap both the chiplet structure 300-1 and the chiplet structure 300-2, both the chiplet structure 300-1 and the memory structure 400-1, or both the chiplet structure 300-2 and the memory structure 400-2.

In some embodiments, the bridge structure 250 may be a bridge die. Specifically the bridge structure 250 may include a silicon body (not shown) and an interconnect structure (not shown) embedded in the silicon body (not shown). The interconnect structure (not shown) may include conductive lines and vias disposed in one or more dielectric layers, and conductive pads formed in the silicon body (not shown). The interconnect structure (not shown) may electrically couple the chiplet structures and the memory structures to each other.

In some embodiments, the semiconductor package assembly 500A uses carrier structures 350-1, 350-2, 450-1 and 450-2 to compensate the differences between the heights of the chiplet structures 300-1, 300-2 and the memory structures 400-1, 400-2 in the direction D120. In addition, the carrier structures 350-1, 350-2, 450-1 and 450-2 may improve thermal dissipation efficiency of the chiplet structures 300-1, 300-2 and the memory structures 400-1, 400-2.

As shown in FIG. 1A, the carrier structure 350-1 is directly bonded to the chiplet structure 300-1. The carrier structure 350-2 is located beside the carrier structure 350-1 and directly bonded to the chiplet structure 300-2. In addition, the carrier structure 450-1 is located beside the carrier structure 350-1 and directly bonded to the memory structure 400-1. The carrier structure 450-2 is located beside the carrier structure 350-2 and directly bonded to the memory structure 400-2. The carrier structures 350-1, 350-2, 450-1 and 450-2 are separated from the conductive structures 322 and 422 via the chiplet structures 300-1, 300-2 and the memory structures 400-1, 400-2. In some embodiments, the top surface 350-1T of the carrier structure 350-1, the top surface 350-2T of the carrier structure 350-2, the top surface 450-1T of the memory structure 400-1, and the top surface 450-1T of the memory structure 400-2 are aligned with each other.

In the direction D120, the carrier structure 350-1 has a height H3-1 and the carrier structure 350-2 has a height H3-2. In addition, the memory structure 400-1 has a height H4-1 and the memory structure 400-2 has a height H4-2. In some embodiments, the height H3-1 is the same as or different from the height H3-2. The height H4-1 is the same as or different from the height H4-2.

In some embodiments, the sum of the height H1-1 of the chiplet structure 300-1 and the height H3-1 of the carrier structure 350-1 is equal to the sum of the height H1-2 of the chiplet structure 300-2 and the height H3-2 of the carrier structure 350-2, the sum of the height H2-1 of the memory structure 400-1 and the height H4-1 of the carrier structure 450-1, and the sum of the height H2-2 of the memory structure 400-2 and the height H4-2 of the carrier structure 450-2. In this embodiment, the height H3-1 is higher than the height H3-2. The height H4-1 is equal to the height H4-2. In addition, the height H3-1 and the height H3-2 are higher than the height H4-1 and the height H4-2. It is noted that the relationship between the heights H3-1 and H3-2, and the relationship between the heights H4-1 and H4-2 are not limited to the disclosed embodiment.

In some embodiments, the semiconductor package assembly 500A further includes thermal dissipation layers 370-1, 370-2, 470-1 and 470-2 disposed on and completely cover the top surface 350-1T, 350-2T, 450-1 and 450-2T of the carrier structures 350-1, 350-2, 450-1 and 450-2. In addition, the thermal dissipation layers 370-1, 370-2, 470-1 and 470-2 may be in contact with the carrier structures 350-1, 350-2, 450-1 and 450-2 to enhance its thermal conductivity. In some embodiments, the thermal dissipation layers 370-1, 370-2, 470-1 and 470-2 may have the same height in the direction D120. Therefore, the total height HT1 of the stack S1 composed of the chiplet structure 300-1, the carrier structure 350-1 and the thermal dissipation layer 370-1, the total height HT2 of the stack S2 composed of the chiplet structure 300-2, the carrier structure 350-2 and the thermal dissipation layer 370-2, the total height HT3 of the stack S3 composed of the memory structure 400-1, the carrier structure 450-1 and the thermal dissipation layer 470-1, and the total height HT4 of the stack S4 composed of the memory structure 400-2, the carrier structure 450-2 and the thermal dissipation layer 470-2 may keep the same value.

In some embodiments, the thermal dissipation layers 370-1, 370-2, 470-1 and 470-2 may be formed of thermal grease, thermal gel, thermal conductive adhesive, phase change material, phase change metal alloy, metal, polymer, another suitable material, or a combination thereof, but it is not limited thereto.

In this embodiment, the thermal dissipation layers 370-1, 370-2, 470-1 and 470-2 may be metallization layers, such as backside metallization (BSM) layers 370-1, 370-2, 470-1 and 470-2. The BSM layers 370-1, 370-2, 470-1 and 470-2 may be a single layer or multi-layer structure. In some embodiments, a seed layer (not shown) may be disposed between the BSM layers 370-1, 370-2, 470-1 and 470-2 of the corresponding carrier structures 350-1, 350-2, 450-1 and 450-2. In some embodiments, the seed layer may include titanium (Ti) and chromium (Cr), another suitable metal material, or a combination thereof. The BSM layers 370-1, 370-2, 470-1 and 470-2 may be formed of aluminum (Al), copper (Cu), nickel (Ni), silver (Ag), gold (Au), another suitable metal material, or a combination thereof. In some embodiments, the BSM layers 370-1, 370-2, 470-1 and 470-2 may be formed a physical vapor deposition (PVD) process, such as sputtering.

In some embodiments, the semiconductor package assembly 500A further includes an underfill 230. The underfill 230 may partially fill the gap between the chiplet structure 300-1 and the substrate 200, the gap between the chiplet structure 300-2 and the substrate 200, the gap between the memory structure 400-1 and the substrate 200, the gap between the memory structure 400-2 and the substrate 200, the gap between the stacks S1 and S2, the gap between the stacks S3 and S1, and the gap between the stacks S4 and S2. As shown in FIG. 1A, upper portions of the of the carrier structures 350-1, 350-2, 450-1 and 450-2 and the thermal dissipation layers 370-1, 370-2, 470-1 and 470-2 may be exposed form the underfill 230.

In some embodiments, the underfill 230 laterally surrounds the conductive structures 322 and 422, the chiplet structures 300-1, 300-2 and the memory structures 400-1, 400-2 and is in contact with a portion of the redistribution layer 210-1 of the substrate 200 to provide structural support and further reduce the thermal resistance from the chiplet structures 300-1 and 300-2, the memory structures 400-1, 400-2 and the carrier structures 350-1, 350-2, 450-1 and 450-2 to the redistribution layer 210-1 of the substrate 200. In addition, the underfill 230 may be disposed to compensate for differing coefficients of thermal expansion (CTEs) between the chiplet structures 300-1, 300-2, the memory structures 400-1, 400-2, the carrier structures 350-1, 350-2, 450-1 and 450-2 and the redistribution layer 210-1 of the substrate 200. In some embodiments, the underfill 230 may be formed of polymer, such as epoxy or another suitable material. In some embodiments, the underfill 230 may be dispensed with capillary force, and then may be cured through any suitable curing process.

As shown in FIG. 1A, the semiconductor package assembly 500A further includes a stiffener ring 260 mounted on the substrate 200 opposite the conductive structures 222 using an adhesive layer (not shown). The stiffener ring 260 may be adhered onto the substrate 200 along edges 200E of the substrate 200. The stiffener ring 260 may laterally surround the stack S1 composed of the chiplet structure 300-1, the carrier structure 350-1 and the thermal dissipation layer 370-1, the stack S2 composed of the chiplet structure 300-2, the carrier structure 350-2 and the thermal dissipation layer 370-2, the stack S3 composed of the memory structure 400-1, the carrier structure 450-1 and the thermal dissipation layer 470-1, and the stack S4 composed of the memory structure 400-2, the carrier structure 450-2 and the thermal dissipation layer 470—are surrounded by the stiffener ring 260.

In some embodiments, the stiffener ring 260 is used for warpage control to reduce the high stress experienced by bonded various materials in the semiconductor package assembly during cycles of heating and cooling. The stiffener ring 260 may provide extra support to the semiconductor package assembly 500A thus reducing warpage, preventing bending, and maintaining planarity of the substrate 200. In some embodiments, the stiffener ring 260 are separated from the underfill 230 by a gap (not shown). In some embodiments, edges 260E of the stiffener ring 260 are leveled with the corresponding edges 200E of the substrate 200. Therefore, the edges 260E of the stiffener ring 260 and the edges 200E of the substrate 200 may collectively serve as edges of the semiconductor package assembly 500A. In some embodiments, the stiffener ring 260 includes molding compound, epoxy, metal (e.g., copper), another suitable material, or a combination thereof, but it is not limited thereto. In some embodiments, the stiffener ring 260 may be formed by a compression molding process, a transfer molding process, a dispensing process, a PVD process, another applicable process, or a combination thereof.

FIG. 1B are cross-sectional views of a semiconductor package assembly 500B in accordance with some embodiments of the disclosure. Elements of the embodiments that are the same or similar to those previously described with reference to FIG. 1A is not repeated herein, in the interests of brevity. In some embodiments, the semiconductor package assembly 500B can be used to form a Chip-on-Wafer-on-Substrate (CoWoS) structure. For example, the semiconductor package assembly 500B may include at least one wafer-level fan-out package 480 (such as a Chip-on-Wafer (CoW) package) and a substrate 200.

In some embodiments, the semiconductor package assembly 500B includes the substrate 200, the fan-out package 480, an underfill 430, a thermal dissipation layer 570, a stiffener ring 260, and conductive structures 222. The fan-out package 480 of the semiconductor package assembly 500B includes chiplet structures 300-1 and 300-2, memory structures 400-1 and 400-2, carrier structures 350-1, 350-2, 450-1 and 450-2, a thermal dissipation layer 570, an underfill 330, a molding compound 240, an interposer 270, one or more bridge structures 550, and conductive structures 282, 322 and 422. The structure, arrangements, materials and processes of the substrate 200, the conductive structures 222, 322 and 422, the chiplet structures 300-1 and 300-2, the memory structures 400-1 and 400-2, the carrier structures 350-1, 350-2, 450-1 and 450-2 and the stiffener ring 260 of the semiconductor package assembly 500B may refer to those of the substrate 200, the conductive structures 222, 322 and 422, the chiplet structures 300-1 and 300-2, the memory structures 400-1 and 400-2, and the carrier structures 350-1, 350-2, 450-1 and 450-2 and the stiffener ring 260 of the semiconductor package assembly 500A, and are not repeated herein, in the interests of brevity.

As shown in FIG. 1B, the fan-out package 480 is mounted on the substrate 200 opposite the conductive structures 222 by a bonding process using conductive structures 282. The conductive structures 282 are in contact with and electrically connected (or coupled) to the interposer 270 and the conductive pads 214 of the substrate 200. In some embodiments, the conductive structures 282 may include a conductive ball structure such as a copper ball, a conductive bump structure such as a copper bump or a solder bump structure, or a conductive pillar structure such as a copper pillar structure. For example, the conductive structures 282 may be controlled collapse chip connection (C4) structures.

In this embodiment, the interposer 270 is disposed on the substrate 200. A stack S11 composed of the chiplet structure 300-1 and the carrier structure 350-1, a stack S21 composed of the chiplet structure 300-2 and the carrier structure 350-2, a stack S31 composed of the memory structure 400-1 and the carrier structure 450-1, and a stack S41 composed of the memory structure 400-2 and the carrier structure 450-2 are mounted on interposer 270 using the conductive structures 322 and 422. In other words, the interposer 270 is located between the substrate 200 and the stacks S11, S21, S31 and S41.

In some embodiments, the interposer 270 may include one or more conductive traces 272, one or more conductive vias 274 disposed in one or more dielectric layers 276 and conductive pads 278. The conductive traces 272 are electrically connected (or coupled) to the corresponding contact pads 278. The conductive pads 278 are exposed to openings of the solder mask layer (not shown) and close to the substrate 200. The conductive elements 322 are disposed on and in contact with the corresponding contact pads 320. Therefore, the conductive elements 282 are electrically connected (or coupled) between the conductive pads 278 of the fan-out package 480 and the conductive pads 214 of the substrate 200.

In some embodiments, the material of the conductive traces 272, the conductive vias 274, and the conductive pads 278 of the interposer 270 may be similar to the material of the conductive layers 208, the conductive vias 212, and the conductive pads 214 of the substrate 200. In addition, the material of the dielectric layers 276 may be similar to the material of the dielectric layers 206. It should be noted that in the interposer 270, the number of conductive traces 272, the number of conductive vias 274, the number of conductive pads 278 and the number of dielectric layers 276 shown in FIG. 1B are only an example and is not a limitation to the present disclosure.

In this embodiment, the bridge structure 550 is embedded in the interposer 270. The bridge structure 550 may be coupled between the chiplet structure 300-1 and the chiplet structure 300-2, between the chiplet structure 300-1 and the memory structure 400-1, and between chiplet structure 300-2 and the memory structure 400-2. In some embodiments, the bridge structure 550 may be disposed in a recess (not shown) formed in the upper portion of the dielectric layers 276 of the interposer 270. The bridge structures 550 may overlap the chiplet structures 300-1, 300-2 and the memory structures 400-1, 400-2 in the direction D120. For example, the bridge structure 550 may vertically overlap both the chiplet structure 300-1 and the chiplet structure 300-2, both the chiplet structure 300-1 and the memory structure 400-1, or both the chiplet structure 300-2 and the memory structure 400-2. In some embodiments, the bridge structures 250 and 550 may have the same or similar structure, materials, and fabrication processes.

In this embodiment, the underfill 330 may partially fill the gap between the chiplet structure 300-1 and the interposer 270, the gap between the chiplet structure 300-2 and the interposer 270, the gap between the memory structure 400-1 and the interposer 270, the gap between the memory structure 400-2 and the interposer 270, the gap between the stacks S11 and S21, the gap between the stacks S31 and S11, and the gap between the stacks S41 and S21. As shown in FIG. 1B, upper portions of the of the carrier structures 350-1, 350-2, 450-1 and 450-2 may be exposed form the underfill 330.

In some embodiments, the underfill 330 laterally surrounds the conductive structures 322 and 422, the chiplet structures 300-1, 300-2 and the memory structures 400-1, 400-2 and is in contact with a portion of the interposer 270 to provide structural support and further reduce the thermal resistance from the chiplet structures 300-1 and 300-2, the memory structures 400-1, 400-2 and the carrier structures 350-1, 350-2, 450-1 and 450-2 to the interposer 270. In addition, the underfill 330 may be disposed to compensate for differing coefficients of thermal expansion (CTEs) between the chiplet structures 300-1, 300-2, the memory structures 400-1, 400-2, the carrier structures 350-1, 350-2, 450-1 and 450-2 and the interposer 270. In some embodiments, the underfills 230 and 330 may have the same or similar structure, materials, and fabrication processes.

In some embodiments, the molding compound 240 is disposed on and in contact with the interposer 270. The molding compound 240 may laterally surround the underfill 330 and the upper portions of the of the carrier structures 350-1, 350-2, 450-1 and 450-2 may be exposed form the underfill 330. The top surfaces 350-1T, 350-2T, 450-1T and 450-2T of the carrier structures 350-1, 350-2, 450-1 and 450-2 may be exposed from the molding compound 240. In some embodiments, the top surface 240T of the molding compound 240 is leveled with the top surfaces 350-1T, 350-2T, 450-1T and 450-2T of the carrier structures 350-1, 350-2, 450-1 and 450-2. In addition, edges 240E of the molding compound 240 are leveled with the corresponding edges 270E of the interposer 270.

In some embodiments, the molding compound 240 may be formed of a nonconductive material, such as an epoxy, a resin, a moldable polymer, or the like. In some embodiments, the molding compound 240 may be formed by a molding process including compression or injection process. For example, the molding compound 240 may be applied while substantially liquid, and then may be cured through a chemical reaction, such as in an epoxy or resin. In some other embodiments, the molding compound 240 may be an ultraviolet (UV) or thermally cured polymer applied as a gel or malleable solid capable of being disposed around the die 220, and then may be cured using a UV or thermally curing process. The molding compound 240 may be cured with a mold (not shown).

As shown in FIG. 1B, the underfill 430 may fill the gap (not shown) between the interposer 270 of the wafer-level fan-out package 480 and the substrate 200. In some embodiments, the underfill 430 surrounds a lower portion of the interposer 270 and the conductive structures 282 and is in contact with a portion of the substrate 200 to further reduce the thermal resistance from the fan-out package 480 to the substrate 200. In addition, the underfill 430 may be disposed to compensate for differing coefficients of thermal expansion (CTEs) between the wafer-level fan-out package 480, the conductive structures 282 and the substrate 200. In some embodiments, the underfills 230, 330 and 430 may have the same or similar structure, materials, and fabrication processes.

In some embodiments, the stiffener ring 260 are separated from the underfills 330, 430 and the molding compound 240 by a gap (not shown).

As shown in FIG. 1B, the thermal dissipation layer 570 is disposed on the molding compound 240. The thermal dissipation layer 570 may completely cover and the top surface 350-1T, 350-2T, 450-1 and 450-2T of the carrier structures 350-1, 350-2, 450-1 and 450-2. The thermal dissipation layer 570 may laterally (along the direction D100) extend over the molding compound 240 and the carrier structures 350-1, 350-2, 450-1 and 450-2. In addition, the thermal dissipation layer 570 may be in contact with the carrier structures 350-1, 350-2, 450-1 and 450-2 to enhance its thermal conductivity. In this embodiment, the thermal dissipation layers 370-1, 370-2, 470-1, 470-2 and 570 may be may have the same or similar structure, materials, and fabrication processes.

In some embodiments, since the total height HT11 of the stack S11, the total height HT21 of the stack S2, the total height HT31 of the stack S3, and the total height HT41 of the stack S4 may keep the substantially same value, the thermal dissipation layer 570 may have planar top and bottom surfaces.

FIG. 1C are cross-sectional views of a semiconductor package assembly 500C in accordance with some embodiments of the disclosure. Elements of the embodiments that are the same or similar to those previously described with reference to FIG. 1A is not repeated herein, in the interests of brevity. In some embodiments, the semiconductor package assembly 500C includes the substrate 200, chiplet structures 300-1 and 300-2, memory structures 400-1 and 400-2, carrier structures 350-1, 350-2, 450-1 and 450-2, thermal dissipation layers 370-1, 370-2, 470-1, 470-2 and 572, an underfill 230, one or more bridge structures 250, a conductive lid 540, and conductive structures 322, 422 and 222. The structure, arrangements, materials and processes of the substrate 200, the conductive structures 222, 322 and 422, the chiplet structures 300-1 and 300-2, the memory structures 400-1 and 400-2, the carrier structures 350-1, 350-2, 450-1 and 450-2, the thermal dissipation layers 370-1, 370-2, 470-1 and 470-2, the underfill 230 and the bridge structures 250 of the semiconductor package assembly 500B may refer to those of the substrate 200, the conductive structures 222, 322 and 422, the chiplet structures 300-1 and 300-2, the memory structures 400-1 and 400-2, the carrier structures 350-1, 350-2, 450-1 and 450-2, the thermal dissipation layers 370-1, 370-2, 470-1 and 470-2, the underfill 230 and the bridge structures 250 of the semiconductor package assembly 500A, and are not repeated herein, in the interests of brevity.

The conductive lid 540 is disposed on the substrate 200. As shown in FIG. 1C, the conductive lid 540 may have an inverted-U shape with a uniform thickness. In some embodiments, the conductive lid 540 may include a top portion 540TP and sidewall portions 540SP. The top portion 540TP of the conductive lid 540 may extend in the direction D100 and completely cover the substrate 200, the stacks S1, S2, S3 and S4 and the underfill 230. The sidewall portions 540SP are connected between the top portion 540TP and the substrate 200. The sidewall portions 540SP may laterally surrounds the stacks S1, S2, S3 and S4 and the underfill 230. Edges 540E of the sidewall portions 540SP may be leveled with the corresponding edges 200E of the substrate 200.

As shown in FIG. 1C, the conductive lid 540 and the underfill 230 may not be in contact with each other. In some embodiments, there is a space between the conductive lid 540 and the underfill 230. In some embodiments, the conductive lid 540 may be made by a metal material, such as copper, aluminum, iron or a combination thereof. In some embodiments, the conductive lid 540 may be made by a non-metal material, such as a ceramic material, a polymer material or another applicable non-metal material. The conductive lid 540 could conduct heat and increase strength of the chiplet structures 300-1 and 300-2 and the memory structures 400-1, 400-2 for reducing warpage.

As shown in FIG. 1C, the thermal dissipation layer 572 is disposed between the top portion 540TP of the conductive lid 540 and the thermal dissipation layers 370-1, 370-2, 470-1 and 470-2. The thermal dissipation layer 572 may laterally (along the direction D100) extend over the underfill 230 and the stacks S1, S2, S3 and S4. The thermal dissipation layer 572 may fill gaps between the upper portions of the of the carrier structures 350-1, 350-2, 450-1 and 450-2 exposed form the underfill 330 and gaps between the thermal dissipation layers 370-1, 370-2, 470-1 and 470-2. In addition, the thermal dissipation layer 572 is in contact with the thermal dissipation layers 370-1, 370-2, 470-1 and 470-2 and the conductive lid 540 to enhance its thermal conductivity.

In this embodiment, the thermal dissipation layer 572 may be a thermal interface material (TIM). In some embodiments, the TIM may include a metal or a metal alloy including Al, Cu, Ni, Co. In addition, the TIM may include diamond, aluminum nitride, boron nitride, etc., or other high thermal conductivity material. In some embodiments, the TIM may be made of a non-metallic material, such as a polymer. This non-metallic TIM has a higher thermal conductivity than the underfill 230, enabling faster heat dissipation.

FIG. 1D are cross-sectional views of a semiconductor package assembly 500D in accordance with some embodiments of the disclosure. Elements of the embodiments that are the same or similar to those previously described with reference to FIG. 1B is not repeated herein, in the interests of brevity. In some embodiments, the semiconductor package assembly 500D can be used to form a Chip-on-Wafer-on-Substrate (CoWoS) structure. For example, the semiconductor package assembly 500D may include at least one wafer-level fan-out package 480 (such as a Chip-on-Wafer (CoW) package) and a substrate 200.

In some embodiments, the semiconductor package assembly 500D includes the substrate 200, the fan-out package 480, an underfill 430, a thermal dissipation layer 572, a conductive lid 540, and conductive structures 222. The fan-out package 480 of the semiconductor package assembly 500B includes chiplet structures 300-1 and 300-2, memory structures 400-1 and 400-2, carrier structures 350-1, 350-2, 450-1 and 450-2, thermal dissipation layer 570, an underfill 330, a molding compound 240, an interposer 270, a conductive lid 540, one or more bridge structures 550, thermal dissipation layers 570 and 572, and conductive structures 282, 322 and 422. The structure, arrangements, materials and processes of the substrate 200, the fan-out package 480 (including the chiplet structures 300-1 and 300-2, the memory structures 400-1 and 400-2, the carrier structures 350-1, 350-2, 450-1 and 450-2, the thermal dissipation layer 570, the underfill 330, the molding compound 240, the interposer 270, the bridge structures 550, and the conductive structures 282, 322 and 422), the underfill 430, the thermal dissipation layer 570, and conductive structures 222 of the semiconductor package assembly 500D may refer to those of the substrate 200, the fan-out package 480 (including the chiplet structures 300-1 and 300-2, the memory structures 400-1 and 400-2, the carrier structures 350-1, 350-2, 450-1 and 450-2, the thermal dissipation layer 570, the underfill 330, the molding compound 240, the interposer 270, the bridge structures 550, and the conductive structures 282, 322 and 422), the underfill 430, the thermal dissipation layer 570, and conductive structures 222 of the semiconductor package assembly 500A, and are not repeated herein, in the interests of brevity.

The conductive lid 540 is disposed on the substrate 200. As shown in FIG. 1D, the conductive lid 540 may have an inverted-U shape with a uniform thickness. In some embodiments, the conductive lid 540 may include a top portion 540TP and sidewall portions 540SP. The top portion 540TP of the conductive lid 540 may extend in the direction D100 and completely cover the substrate 200, the fan-out package 480 and the underfill 430. The sidewall portions 540SP are connected between the top portion 540TP and the substrate 200. The sidewall portions 540SP may laterally surrounds the fan-out package 480 and the underfill 430. Edges 540E of the sidewall portions 540SP may be leveled with the corresponding edges 200E of the substrate 200.

As shown in FIG. 1D, the conductive lid 540 is not contact with the fan-out package 480, the underfill 430 and the thermal dissipation layer 570. In some embodiments, there is a space between the conductive lid 540 and the fan-out package 480, the underfill 430 and the thermal dissipation layer 570.

As shown in FIG. 1D, the thermal dissipation layer 572 is disposed between the top portion 540TP of the conductive lid 540 and the thermal dissipation layer 570. The thermal dissipation layer 572 may laterally (along the direction D100) extend over the fan-out package 480. In addition, the thermal dissipation layer 572 is in contact with the thermal dissipation layer 570 and the conductive lid 540 to enhance its thermal conductivity.

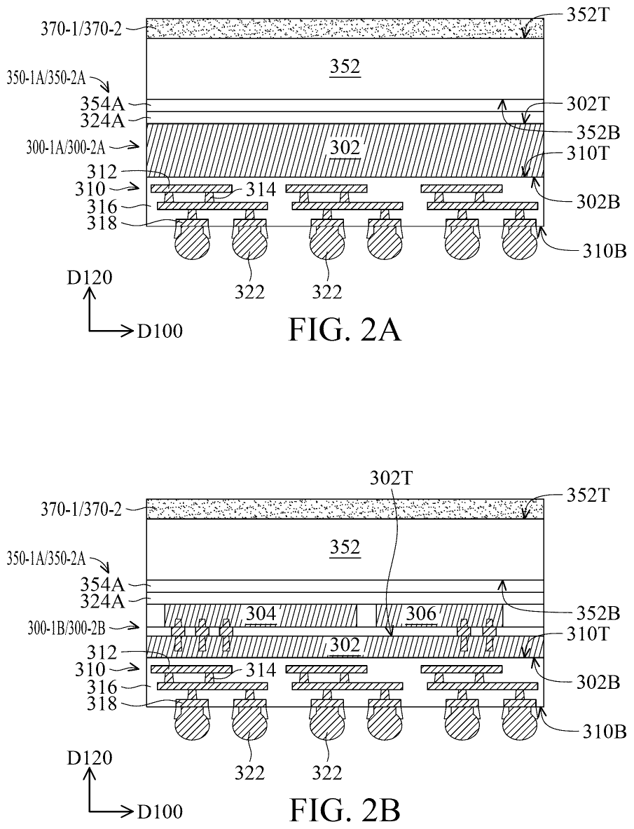

FIG. 2A is a cross-sectional view of a carrier structure 350-1A (or a carrier structure 350-2A) and a chiplet structure 300-1A (or a chiplet structure 300-2A) the of the semiconductor package assembly 500A (or the semiconductor package assemblies 500B-500D) in accordance with some embodiments of the disclosure, showing the bonding between the carrier structure 350-1A/350-2A and the chiplet structure 300-1A/300-2A. Elements of the embodiments that are the same or similar to those previously described with reference to FIGS. 1A and 1B are not repeated herein, in the interests of brevity.

As shown in FIG. 2A, the chiplet structure 300-1A/300-2A may include a semiconductor die 302 (also called a chiplet 302) and a redistribution layer (RDL) structure 310. In this embodiment, the chiplet structure 300-1A/300-2A may include a single semiconductor die 302.

The semiconductor die 302 has a top surface 302T and a bottom surface 302B. Conductive pads (not shown) of the semiconductor die 302 are disposed close to the bottom surface 302B to be electrically connected to the circuitry (not shown) of the semiconductor die 302. Therefore, the bottom surface 302B of the semiconductor die 302 also serves as an active surface of the semiconductor die 302. In some embodiments, the semiconductor die 302 is fabricated by a flip-chip technology. In addition, the semiconductor die 302 is flipped to be disposed on the RDL structure 310 opposite the conductive structures 322. The bottom surface 302B (i.e., the active surface) of the semiconductor die 302 may face the RDL structure 310.

The RDL structure 310 is located below and coupled to bottom surface 302B of the semiconductor die 302. The conductive pads (not shown) of the semiconductor die 302 are coupled to the RDL structure 310. The RDL structure 310 may include one or more conductive traces 312, one or more vias 314 disposed in one or more dielectric layers 316, and conductive pads 318. The conductive traces 312 may be electrically connected to the corresponding conductive vias 314 and conductive pads 318. The conductive pads 318 and/or the conductive traces 312 are exposed to openings of solder mask layers (not shown) disposed close to the top surface 310T and the bottom surface 310B. In one embodiment, the conductive traces 312 may include power trace segments, signal trace segments or ground trace segments, which are used for the input/output (I/O) connections of the first semiconductor die 302. Also, the conductive pads 318 are disposed on the top surface 310T and the bottom surface 310B of the RDL structure 310, connected to different terminals of the conductive traces 312. The conductive pads 318 on the bottom surface 310B of the RDL structure 310 are used for the conductive structures 322 that are mounted directly on them.

In some embodiments, the chiplet structure 300-1A/300-2A further include a bonding layer 324A disposed on the top surface 302T of the first semiconductor die 302. In some embodiments, the bonding layer 324A may include a metal layer, a dielectric layer, or metal patterns passing through a dielectric layer combination thereof. In some embodiments, the dielectric layer includes oxide-base dielectric materials. In this embodiment, the bonding layer 324A may include a metal layer or a dielectric layer.

As shown in FIG. 2A, the carrier structure 350-1A/350-2A may include a semiconductor carrier 352 and a bonding layer 354A. The semiconductor carrier 352 has a top surface 352T (also serve as the top surface 350-1T/350-2T of the carrier structure 350-1/350-2 of FIG. 1A) away from the chiplet structure 300-1/300-2 and a bottom surface 352B close to the chiplet structure 300-1/300-2. In some embodiments, the semiconductor carrier 352 may be formed of semiconductor materials, such as silicon (Si) or silicon carbide (SiC). The semiconductor carrier 352 may help to dissipate heat generated from the chiplet structure 300-1A/300-2A.

The bonding layer 354A is located below the semiconductor carrier 352. More specifically, the bonding layer 354A is disposed on the bottom surface 352B of semiconductor carrier 352. In addition, the bonding layer 354A faces and is directly bonded to the bonding layer 324A of the chiplet structure 300-1/300-2 (without air gap between the bonding layers 324A and 354A) to improve thermal dissipation efficiency. In some embodiments, the bonding layer 354A may include a metal layer, a dielectric layer, or metal patterns passing through a dielectric layer combination thereof. In some embodiments, the bonding layers 324A and 354A have the same material and structure. For example, when the bonding layers 324A and 354A are dielectric layers formed of the same dielectric material, the carrier structure 350-1A/350-2A is fusion bonded to the corresponding chiplet structure 300-1/300-2. When the bonding layers 324A and 354A are metal layers formed of the same metal material, the carrier structure 350-1A/350-2A is metal bonded to the corresponding chiplet structure 300-1A/300-2A.

FIG. 2B is a cross-sectional view of the carrier structure 350-1A (or the carrier structure 350-2A) and a chiplet structure 300-1B (or a chiplet structure 300-2B) the of the semiconductor package assembly 500A (or the semiconductor package assemblies 500B-500D) in accordance with some embodiments of the disclosure, showing the bonding between the carrier structure 350-1A/350-2A and a chiplet structure 300-1B/300-2B. Elements of the embodiments that are the same or similar to those previously described with reference to FIG. 2A is not repeated herein, in the interests of brevity. As shown in FIGS. 2A and 2B, the difference between the chiplet structure 300-1A/300-2A and the chiplet structure 300-1B/300-2B at least includes that the chiplet structure 300-1B/300-2B further includes semiconductor dies 304 and 306 (also called chiplets 304 and 306).

The semiconductor dies 304 and 306 are disposed on the RDL structure 310 and coupled to the semiconductor die 302. More specifically, the semiconductor dies 304 and 306 are arranged side-by-side in the direction D100 and overlap the semiconductor die 302 in the direction D120. In addition, the sizes of the semiconductor dies 304 and 306 may be smaller than the size of the semiconductor die 302, and a molding compound (not shown) may be disposed to surround the semiconductor dies 304 and 306. In some embodiments, the semiconductor dies 304 and 306 may be coupled to the semiconductor die 302 by hybrid bonding. In some embodiments, the semiconductor dies 302, 304 and 306 may have different critical dimensions (CD) and/or functions. In some embodiments, the number and arrangements of the semiconductor dies in the same chiplet structure 300-1B/300-2B are not limited to the disclosure embodiments.

In some embodiments, the chiplet structure 300-1B/300-2B further include a bonding layer 324A disposed on the top surfaces 304T and 306T of the semiconductor dies 304 and 306. The carrier structure 350-1A/350-2A are bonded to the chiplet structure 300-1B/300-2B via the bonding layers 324A and 354A. The bonding layer 354A of the carrier structure 350-1A/350-2A is directly bonded to the bonding layer 324A of the chiplet structure 300-1B/300-2B.

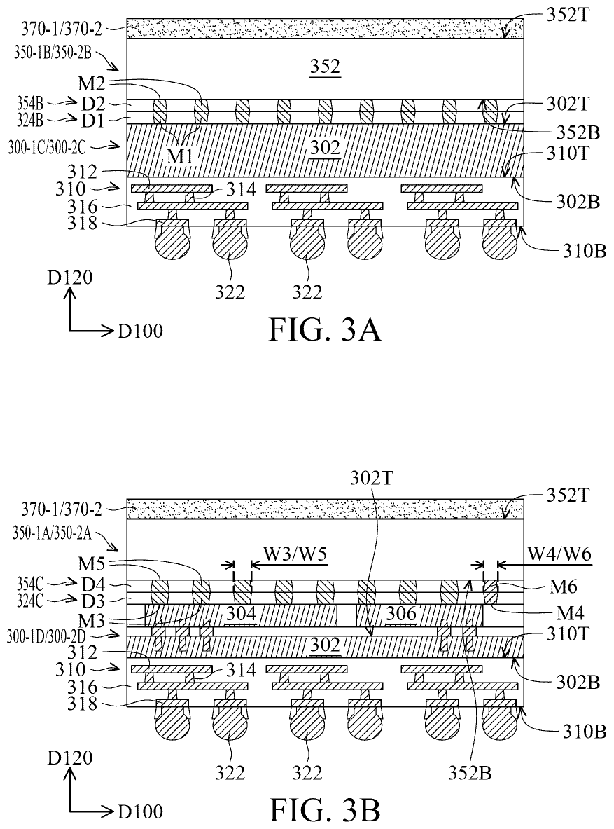

FIG. 3A is a cross-sectional view of a carrier structure 350-1B (or a carrier structure 350-2B) and a chiplet structure 300-1C (or a chiplet structure 300-2C) the of the semiconductor package assembly 500A (or the semiconductor package assemblies 500B-500D) in accordance with some embodiments of the disclosure, showing the bonding between the carrier structure 350-1B/350-2B and a chiplet structure 300-1C/300-2C. Elements of the embodiments that are the same or similar to those previously described with reference to FIG. 2A are not repeated herein, in the interests of brevity.

Compared with the chiplet structure 300-1A/300-2A, the chiplet structure 300-1C/300-2C includes a bonding layer 324B disposed on the top surface 302T of the semiconductor die 302. In this embodiment, the bonding layer 324B may include metal patterns M1 passing through a dielectric layer D1 in order to further reduce the thermal resistance from the semiconductor die 302. In some embodiments, the metal patterns M1 may include metal traces and/or metal pads. In some embodiments, the metal patterns M1 may be electrical floating.

Compared with the carrier structure 350-1A/350-2A, the carrier structure 350-1B/350-2B includes a bonding layer 354B is located below the semiconductor carrier 352. More specifically, the bonding layer 354B is disposed on the bottom surface 352B of semiconductor carrier 352. In addition, the bonding layer 354B faces and is directly bonded to the bonding layer 324B of the chiplet structure 300-1C/300-2C.

In some embodiments, the bonding layers 324B and 354B have the same material and structure. For example, the bonding layer 354B may include metal patterns M2 passing through a dielectric layer D2. The metal patterns M2 may be disposed directly on and completely overlap the corresponding metal patterns M1. In some embodiments, the metal patterns M1 and M2 may have the same dimensions. The dielectric layer D2 may be disposed directly on and completely overlap the dielectric layer D1.

In this embodiment, the carrier structure 350-1B/350-2B is hybrid bonded to the corresponding chiplet structure 300-1C/300-2C. More specifically, the metal patterns M1 are directly bonded (metal bonded) to the corresponding metal patterns M2. The dielectric layer D1 is directly bonded (fusion bonded) to the dielectric layer D2.

FIG. 3B is a cross-sectional view of the carrier structure 350-1C (or the carrier structure 350-2C) and a chiplet structure 300-1D (or a chiplet structure 300-2D) the of the semiconductor package assembly 500A (or the semiconductor package assemblies 500B-500D) in accordance with some embodiments of the disclosure, showing the bonding between the carrier structure 350-1C/350-2C and a chiplet structure 300-1D/300-2D. Elements of the embodiments that are the same or similar to those previously described with reference to FIG. 2B are not repeated herein, in the interests of brevity.

Compared with the chiplet structure 300-1B/300-2B, the chiplet structure 300-1D/300-2D includes a bonding layer 324C disposed on the top surfaces 304T and 306T of the semiconductor dies 304 and 306. In this embodiment, the bonding layer 324C may include metal patterns M3, M4 passing through a dielectric layer D3 in order to further reduce the thermal resistance from the semiconductor die 302. In some embodiments, the metal patterns M3, M4 may include metal traces and/or metal pads. In some embodiments, the metal patterns M3, M4 may be electrical floating.

As shown in FIG. 3B, the metal patterns M3 disposed directly on the top surfaces 304T and 306T of the semiconductor dies 304 and 306 may have a width W3. The metal patterns M4 disposed without overlapping the top surfaces 304T and 306T of the semiconductor dies 304 and 306 may have a width W4. In some embodiments, the width W3 may be wider than the width W4 to improve the thermal dissipation capability of the chiplet structure 300-1D/300-2D.

Compared with the carrier structure 350-1A/350-2A, the carrier structure 350-1C/350-2C includes a bonding layer 354C is located below the semiconductor carrier 352. More specifically, the bonding layer 354C is disposed on the bottom surface 352B of semiconductor carrier 352. In addition, the bonding layer 354C faces and is directly bonded to the bonding layer 324C of the chiplet structure 300-1D/300-2D.

In some embodiments, the bonding layers 324C and 354C have the same material and structure. For example, the bonding layer 354C may include metal patterns M5, M6 passing through a dielectric layer D4. The metal patterns M5 may be disposed directly on and completely overlap the corresponding metal patterns M3. The metal patterns M6 may be disposed directly on and completely overlap the corresponding metal patterns M4. In some embodiments, the metal patterns M3 and M5 may have the same dimensions. The metal patterns M4 and M6 may have the same dimensions. For example, the width W5 of the metal pattern M5 may be wider than the width W6 of the metal pattern M6. The dielectric layer D4 may be disposed directly on and completely overlap the dielectric layer D3.

In this embodiment, the carrier structure 350-1C/350-2C is hybrid bonded to the corresponding chiplet structure 300-1D/300-2D. More specifically, the metal patterns M3 are directly bonded (metal bonded) to the corresponding metal patterns M5. The metal patterns M4 are directly bonded (metal bonded) to the corresponding metal patterns M6. The dielectric layer D3 is directly bonded (fusion bonded) to the dielectric layer D4.

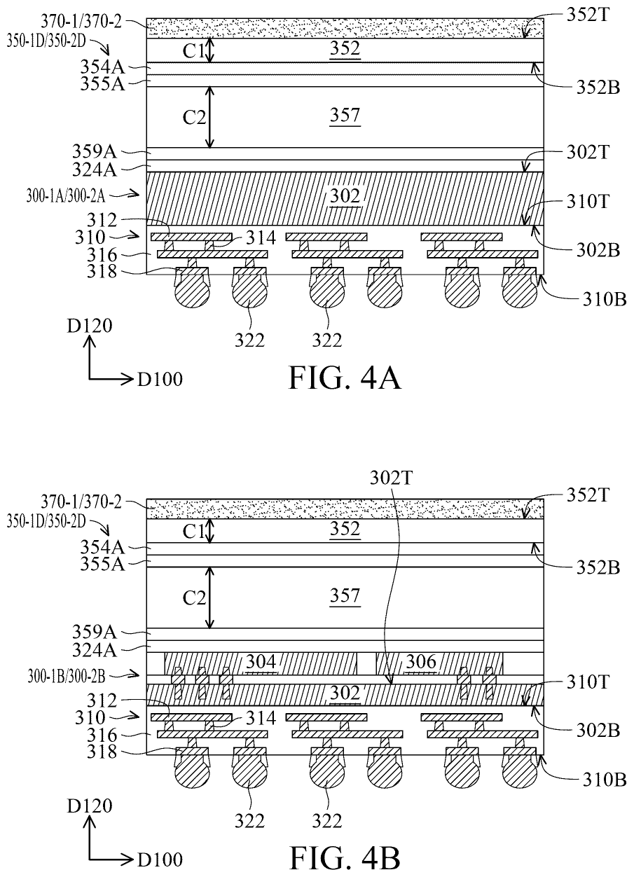

FIG. 4A is a cross-sectional view of a carrier structure 350-1D (or a carrier structure 350-2D) and the chiplet structure 300-1A (or the chiplet structure 300-2A) the of the semiconductor package assembly 500A (or the semiconductor package assemblies 500B-500D) in accordance with some embodiments of the disclosure, showing the bonding between the carrier structure 350-1D/350-2D and the chiplet structure 300-1A/300-2A. Elements of the embodiments that are the same or similar to those previously described with reference to FIG. 2A are not repeated herein, in the interests of brevity. As shown in FIGS. 2A and 4A, the difference between the carrier structure 350-1A/350-2A and the carrier structure 350-1D/350-2D at least includes that the carrier structure 350-1D/350-2D includes multiple semiconductor carriers and bonding layers on the top and bottom surfaces of each of the semiconductor carriers. In this embodiment, the thickness of the carrier structure 350-1D/350-2D may be tunable by adjusting the thicknesses of the semiconductor carriers.

As shown in FIG. 4A, compared to the carrier structure 350-1A/350-2A, the carrier structure 350-1D/350-2D may include the semiconductor carrier 352, a semiconductor carrier 357, the bonding layer 354A and bonding layer 355A, 359A. The semiconductor carrier 357 is located between the bonding layer 354A and the bonding layer 324A of the chiplet structure 300-1A/300-2A. In some embodiments, the semiconductor carriers 352, 357 may have the same or similar material and structure. In some embodiments, the height C1 of the semiconductor carrier 352 may be the same as or different from the height C2 of the semiconductor carrier 357 the direction D120.

The bonding layer 355A is disposed between the bonding layer 354A and the second semiconductor carrier 357 of the carrier structure 350-1D/350-2D. In some embodiments, the bonding layer 354A and the bonding layer 355A of the carrier structure 350-1D/350-2D have the same material and structure. For example, when the bonding layers 354A and 355A are dielectric layers formed of the same dielectric material, the bonding layer 354A is fusion bonded to the bonding layer 355A. When the bonding layers 354A and 355A are metal layers formed of the same metal material, the bonding layer 354A is metal bonded to the bonding layer 355A.

The bonding layer 359A disposed between the semiconductor carrier 357 of the carrier structure 350-1D/350-2D and the bonding layer 324A of the chiplet structure 300-1A/300-2A. In some embodiments, the bonding layer 324A of the chiplet structure 300-1A/300-2A and the bonding layer 359A of the carrier structure 350-1D/350-2D have the same material and structure. For example, when the bonding layers 359A and 324A are dielectric layers formed of the same dielectric material, the carrier structure 350-1D/350-2D is fusion bonded to the corresponding chiplet structure 300-1A/300-2A. When the bonding layers 359A and 324A are metal layers formed of the same metal material, the carrier structure 350-1D/350-2D is metal bonded to the corresponding chiplet structure 300-1A/300-2A.

FIG. 4B is a cross-sectional view of the carrier structure 350-1D (or the carrier structure 350-2D) and the chiplet structure 300-1B (or the chiplet structure 300-2B) the of the semiconductor package assembly 500A (or the semiconductor package assemblies 500B-500D) in accordance with some embodiments of the disclosure, showing the bonding between the carrier structure 350-1D/350-2D and the chiplet structure 300-1B/300-2B. Elements of the embodiments that are the same or similar to those previously described with reference to FIG. 4A are not repeated herein, in the interests of brevity. As shown in FIGS. 4A and 4B, the difference between the chiplet structure 300-1A/300-2A and the chiplet structure 300-1B/300-2B at least includes that the chiplet structure 300-1B/300-2B further includes semiconductor dies 304 and 306 (also called chiplets 304 and 306).

As shown in FIG. 4B, compared to the carrier structure 350-1A/350-2A, the carrier structure 350-1D/350-2D may include the semiconductor carrier 352, a semiconductor carrier 357, the bonding layer 354A and bonding layer 355A, 359A. The semiconductor carrier 357 is located between the bonding layer 354A and the bonding layer 324A of the chiplet structure 300-1B/300-2B. In some embodiments, the semiconductor carriers 352, 357 may have the same or similar material and structure. In some embodiments, the semiconductor carriers 352, 357 may have the same or different height in the direction D120.

The bonding layer 355A is disposed between the bonding layer 354A and the second semiconductor carrier 357 of the carrier structure 350-1D/350-2D. In some embodiments, the bonding layer 354A and the bonding layer 355A of the carrier structure 350-1D/350-2D have the same material and structure. For example, when the bonding layers 354A and 355A are dielectric layers formed of the same dielectric material, the bonding layer 354A is fusion bonded to the bonding layer 355A. When the bonding layers 354A and 355A are metal layers formed of the same metal material, the bonding layer 354A is metal bonded to the bonding layer 355A.

The bonding layer 359A disposed between the semiconductor carrier 357 of the carrier structure 350-1D/350-2D and the bonding layer 324A of the chiplet structure 300-1B/300-2B. In some embodiments, the bonding layer 324A of the chiplet structure 300-1B/300-2B and the bonding layer 359A of the carrier structure 350-1D/350-2D have the same material and structure. For example, when the bonding layers 359A and 324A are dielectric layers formed of the same dielectric material, the carrier structure 350-1D/350-2D is fusion bonded to the corresponding chiplet structure 300-1B/300-2B. When the bonding layers 359A and 324A are metal layers formed of the same metal material, the carrier structure 350-1D/350-2D is metal bonded to the corresponding chiplet structure 300-1B/300-2B.

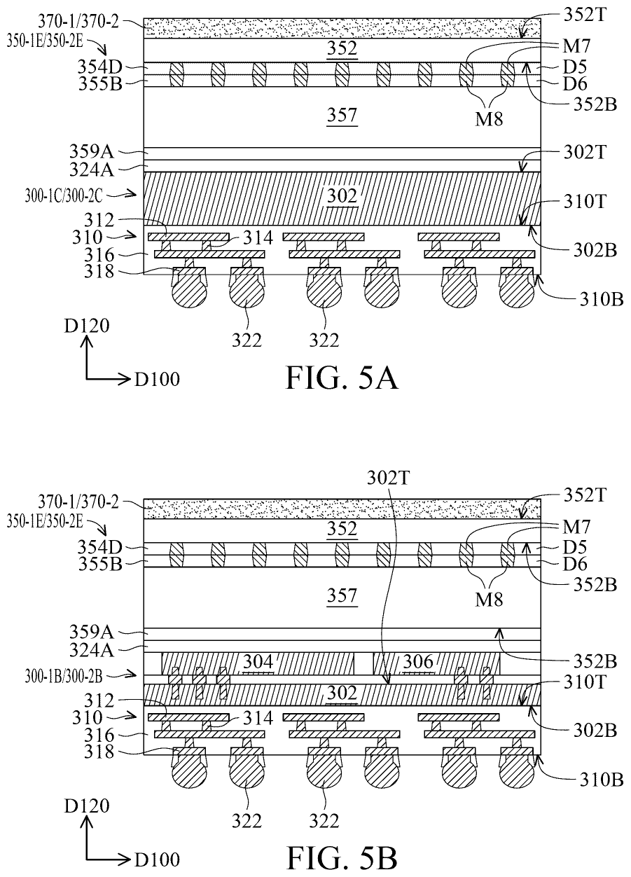

FIG. 5A is a cross-sectional view of a carrier structure 350-1E (or a carrier structure 350-2E) and the chiplet structure 300-1A (or the chiplet structure 300-2A) the of the semiconductor package assembly 500A (or the semiconductor package assemblies 500B-500D) in accordance with some embodiments of the disclosure, showing the bonding between the carrier structure 350-1E/350-2E and the chiplet structure 300-1A/300-2A. FIG. 5B is a cross-sectional view of a carrier structure 350-1E (or a carrier structure 350-2E) and the chiplet structure 300-1B (or the chiplet structure 300-2B) the of the semiconductor package assembly 500A (or the semiconductor package assemblies 500B-500D) in accordance with some embodiments of the disclosure, showing the bonding between the carrier structure 350-1E/350-2E and the chiplet structure 300-1B/300-2B. Elements of the embodiments that are the same or similar to those previously described with reference to FIGS. 3A, 3B, 4A and 4B are not repeated herein, in the interests of brevity.

Compared with the carrier structure 350-1D/350-2D, the carrier structure 350-1E/350-2E includes the semiconductor carriers 352, 357, the bonding layer 359A, and bonding layers 354D and 355B.

The bonding layer 354D is located below the semiconductor carrier 352. More specifically, the bonding layer 354C is between the semiconductor carrier 352 and the bonding layer 355B. In addition, the bonding layer 354D faces and is directly bonded to the bonding layer 355B of the carrier structure 350-1E/350-2E.

The bonding layer 355B is disposed between the bonding layer 354D and the second semiconductor carrier 357 of the carrier structure 350-1E/350-2E. In this embodiment, the bonding layer 354D and the bonding layer 355B of the carrier structure 350-1E/350-2E have the same material and structure. For example, the bonding layer 354D may include metal patterns M7 passing through a dielectric layer D5. The bonding layer 355B may include metal patterns M8 passing through a dielectric layer D6. The metal patterns M7 may be disposed directly on and completely overlap the corresponding metal patterns M8. In some embodiments, the metal patterns M7 and M8 may have the same dimensions and completely overlap each other. The dielectric layer D5 may be disposed directly on and completely overlap the dielectric layer D6.

In this embodiment, the semiconductor carrier 352 is hybrid bonded to the corresponding the semiconductor carrier 357 via the bonding layers 354D and 355B. More specifically, the metal patterns M7 are directly bonded (metal bonded) to the corresponding metal patterns M8. The dielectric layer D5 is directly bonded (fusion bonded) to the dielectric layer D6.

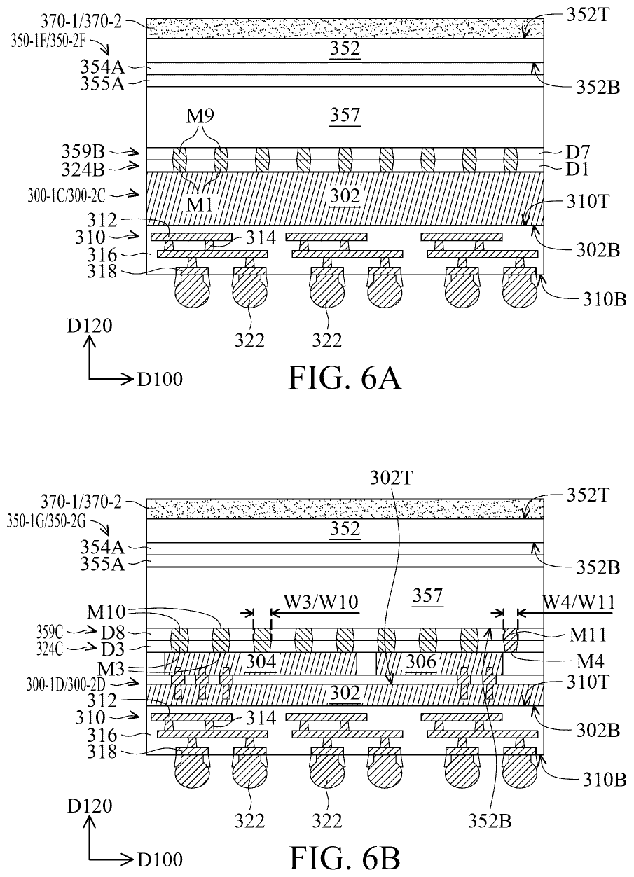

FIG. 6A is a cross-sectional view of a carrier structure 350-1F (or a carrier structure 350-2F) and the chiplet structure 300-1C (or the chiplet structure 300-2C) the of the semiconductor package assembly 500A in accordance with some embodiments of the disclosure, showing the bonding between the carrier structure 350-1F/350-2F and the chiplet structure 300-1C/300-2C. Elements of the embodiments that are the same or similar to those previously described with reference to FIGS. 3A and 4A are not repeated herein, in the interests of brevity.

Compared with the carrier structure 350-1D/350-2D, the carrier structure 350-1F/350-2F includes the semiconductor carriers 352, 357, the bonding layers 354A and 355A, and a bonding layer 359B. The bonding layer 359B disposed between the semiconductor carrier 357 of the carrier structure 350-1F/350-2F and the bonding layer 324B of the chiplet structure 300-1C/300-2C. In some embodiments, the bonding layer 324B of the chiplet structure 300-1C/300-2C and the bonding layer 359B of the carrier structure 350-1C/350-2C have the same material and structure.

For example, the bonding layer 359B may include metal patterns M9 passing through a dielectric layer D7. The metal patterns M9 may be disposed directly on and completely overlap the corresponding metal patterns M1. In some embodiments, the metal patterns M1 and M9 may have the same dimensions. The dielectric layer D7 may be disposed directly on and completely overlap the dielectric layer D1.

In this embodiment, the carrier structure 350-1F/350-2F is hybrid bonded to the corresponding chiplet structure 300-1C/300-2C. More specifically, the metal patterns M1 are directly bonded to the corresponding metal patterns M9. The dielectric layer D1 is directly bonded to the dielectric layer D7.

FIG. 6B is a cross-sectional view of a carrier structure 350-1G (or a carrier structure 350-2G) and the chiplet structure 300-1D (or the chiplet structure 300-2D) the of the semiconductor package assembly 500A in accordance with some embodiments of the disclosure, showing the bonding between the carrier structure 350-1G/350-2G and the chiplet structure 300-1D/300-2D. Elements of the embodiments that are the same or similar to those previously described with reference to FIGS. 3B and 4B are not repeated herein, in the interests of brevity.

Compared with the carrier structure 350-1C/350-2C, the carrier structure 350-1G/350-2G includes the semiconductor carriers 352, 357, the bonding layers 354A and 355A, and a bonding layer 359C. The bonding layer 359C disposed between the semiconductor carrier 357 of the carrier structure 350-1G/350-2G and the bonding layer 324C of the chiplet structure 300-1D/300-2D.

In some embodiments, the bonding layer 324C of the chiplet structure 300-1D/300-2D and the bonding layer 359C of the carrier structure 350-1G/350-2G have the same material and structure. For example, the bonding layer 359C may include metal patterns M10, M11 passing through a dielectric layer D8. The metal patterns M10 may be disposed directly on and completely overlap the corresponding metal patterns M3. The metal patterns M11 may be disposed directly on and completely overlap the corresponding metal patterns M4. In some embodiments, the metal patterns M3 and M10 may have the same dimensions. The metal patterns M4 and M11 may have the same dimensions. For example, the width W10 of the metal pattern M10 may be wider than the width W11 of the metal pattern M11. The dielectric layer D8 may be disposed directly on and completely overlap the dielectric layer D3.

In this embodiment, the carrier structure 350-1G/350-2G is hybrid bonded to the corresponding chiplet structure 300-1D/300-2D. More specifically, the metal patterns M3 are directly bonded to the corresponding metal patterns M10. The metal patterns M4 are directly bonded to the corresponding metal patterns M11. The dielectric layer D3 is directly bonded to the dielectric layer D8.

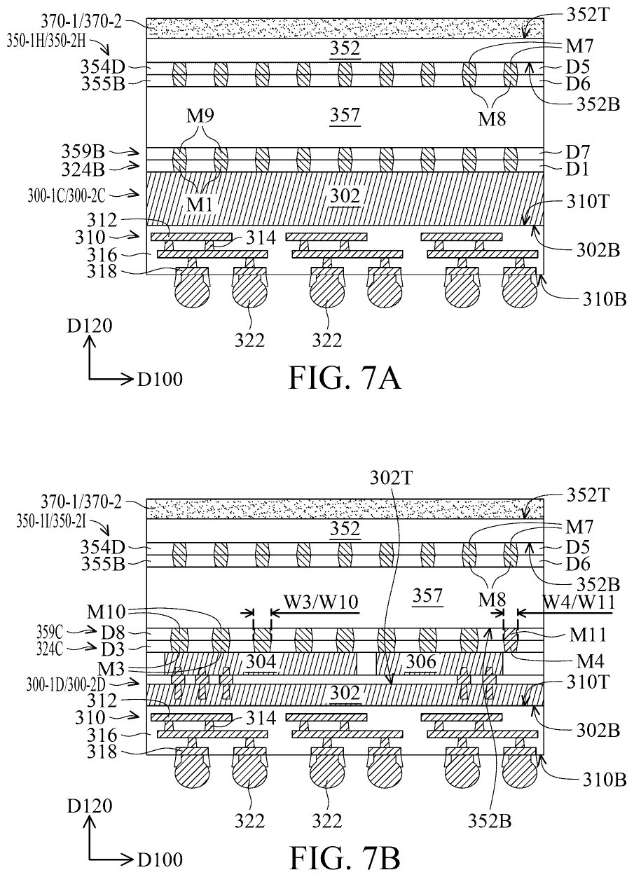

FIG. 7A is a cross-sectional view of a carrier structure 350-1H (or a carrier structure 350-2H) and the chiplet structure 300-1C (or the chiplet structure 300-2C) the of the semiconductor package assembly 500A (or the semiconductor package assemblies 500B-500D) in accordance with some embodiments of the disclosure, showing the bonding between the carrier structure 350-1H/350-2H and the chiplet structure 300-1C/300-2C. Elements of the embodiments that are the same or similar to those previously described with reference to FIGS. 5A and 5B are not repeated herein, in the interests of brevity.

Compared with the carrier structure 350-1F/350-2F, the carrier structure 350-1H/350-2H includes the semiconductor carriers 352, 357, and the bonding layers 354D, 355B and 359B.

The bonding layer 354D is located below the semiconductor carrier 352. More specifically, the bonding layer 354D is between the semiconductor carrier 352 and the bonding layer 355B. In addition, the bonding layer 354D faces and is directly bonded to the bonding layer 355B of the carrier structure 350-1H/350-2H.

The bonding layer 355B is disposed between the bonding layer 354D and the second semiconductor carrier 357 of the carrier structure 350-1H/350-2H. In this embodiment, the bonding layer 354D and the bonding layer 355B of the carrier structure 350-1H/350-2H have the same material and structure. For example, the bonding layer 354D may include metal patterns M7 passing through a dielectric layer D5. The bonding layer 355B may include metal patterns M8 passing through a dielectric layer D6. The metal patterns M7 may be disposed directly on and completely overlap the corresponding metal patterns M8. In some embodiments, the metal patterns M7 and M8 may have the same dimensions and completely overlap each other. The dielectric layer D5 may be disposed directly on and completely overlap the dielectric layer D6.

In this embodiment, the semiconductor carrier 352 is hybrid bonded to the corresponding the semiconductor carrier 357 via the bonding layers 354D and 355B. More specifically, the metal patterns M7 are directly bonded (metal bonded) to the corresponding metal patterns M8. The dielectric layer D5 is directly bonded (fusion bonded) to the dielectric layer D6.

FIG. 7B is a cross-sectional view of a carrier structure 350-1I (or a carrier structure 350-2I) and the chiplet structure 300-1D (or the chiplet structure 300-2D) the of the semiconductor package assembly 500A (or the semiconductor package assemblies 500B-500D) in accordance with some embodiments of the disclosure, showing the bonding between the carrier structure 350-1I/350-2I and the chiplet structure 300-1D/300-2D. Elements of the embodiments that are the same or similar to those previously described with reference to FIGS. 6A and 6B are not repeated herein, in the interests of brevity.

Compared with the carrier structure 350-1G/350-2G, the carrier structure 350-1I/350-2I includes the semiconductor carriers 352, 357, and the bonding layers 354D, 355B and 359C.

The bonding layer 354D is located below the semiconductor carrier 352. More specifically, the bonding layer 354D is between the semiconductor carrier 352 and the bonding layer 355B. In addition, the bonding layer 354D faces and is directly bonded to the bonding layer 355B of the carrier structure 350-1I/350-2I.

The bonding layer 355B is disposed between the bonding layer 354D and the second semiconductor carrier 357 of the carrier structure 350-1I/350-2I. In this embodiment, the bonding layer 354D and the bonding layer 355B of the carrier structure 350-1I/350-2I have the same material and structure. For example, the bonding layer 354D may include metal patterns M7 passing through a dielectric layer D5. The bonding layer 355B may include metal patterns M8 passing through a dielectric layer D6. The metal patterns M7 may be disposed directly on and completely overlap the corresponding metal patterns M8. In some embodiments, the metal patterns M7 and M8 may have the same dimensions and completely overlap each other. The dielectric layer D5 may be disposed directly on and completely overlap the dielectric layer D6.

In this embodiment, the semiconductor carrier 352 is hybrid bonded to the corresponding the semiconductor carrier 357 via the bonding layers 354D and 355B. More specifically, the metal patterns M7 are directly bonded (metal bonded) to the corresponding metal patterns M8. The dielectric layer D5 is directly bonded (fusion bonded) to the dielectric layer D6.

FIG. 8 is a cross-sectional view of a carrier structure 450-1A (or a carrier structure 450-2A) and the memory structure 400-1A (or the memory structure 400-2A) of the semiconductor package assembly 500A (or the semiconductor package assemblies 500B-500D) in accordance with some embodiments of the disclosure. Elements of the embodiments that are the same or similar to those previously described with reference to FIGS. 1 and 2A are not repeated herein, in the interests of brevity.

In some embodiments, the memory structure 400-1A/400-2A further include a bonding layer 424A disposed on the top surface 402T of the topmost memory die 402. In some embodiments, the bonding layers 324A and 424A may have the same or similar material and structure. In this embodiment, the bonding layer 424A may include a metal layer or a dielectric layer.

As shown in FIG. 8, the carrier structure 450-1A/450-2A may include a semiconductor carrier 452 and a bonding layer 454A. The semiconductor carrier 452 has a top surface 452T (also serve as the top surface 450-1T/450-2T of the carrier structure 450-1/450-2 of FIG. 1A) away from the memory structure 400-1A/400-2A and a bottom surface 452B close to the memory structure 400-1A/400-2A. In some embodiments, the semiconductor carrier 352 and 452 may have the same or similar material and structure.

The bonding layer 454A is located below the semiconductor carrier 452. More specifically, the bonding layer 454A is disposed on the bottom surface 452B of semiconductor carrier 452. In addition, the bonding layer 454A faces and is directly bonded to the bonding layer 424A of the memory structure 400-1/400-2. In some embodiments, the bonding layers 354A and 454A may have the same or similar material and structure. In some embodiments, the bonding layers 424A and 454A have the same material and structure. For example, when the bonding layers 424A and 454A are dielectric layers formed of the same dielectric material, the carrier structure 450-1A/450-2A is fusion bonded to the corresponding memory structure 400-1/400-2. When the bonding layers 424A and 454A are metal layers formed of the same metal material, the carrier structure 450-1A/450-2A is metal bonded to the corresponding memory structure 400-1A/400-2A.

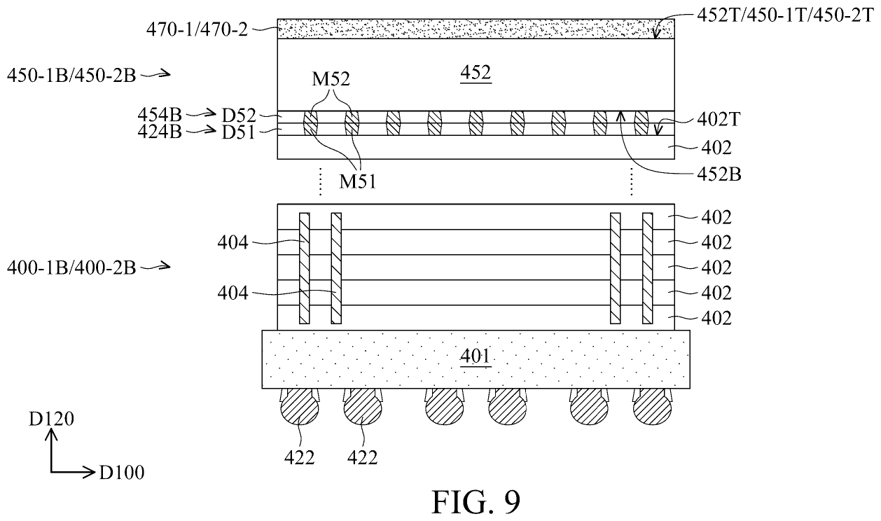

FIG. 9 is a cross-sectional view of a carrier structure 450-1B (or a carrier structure 450-2B) and the memory structure 400-1B (or the memory structure 400-2B) of the semiconductor package assembly 500A (or the semiconductor package assemblies 500B-500D) in accordance with some embodiments of the disclosure. Elements of the embodiments that are the same or similar to those previously described with reference to FIGS. 1, 3A and 8 are not repeated herein, in the interests of brevity.

Compared with the memory structure 400-1A/400-2A, the memory structure 400-1B/400-2B includes a bonding layer 424B disposed on the top surface 402T of the topmost memory die 402. In some embodiments, the bonding layers 324B and 424B may have the same or similar material and structure. In this embodiment, the bonding layer 424B may include metal patterns M51 passing through a dielectric layer D51 in order to further reduce the thermal resistance from the memory dies 402. In some embodiments, the metal patterns M51 may include metal traces and/or metal pads. In some embodiments, the metal patterns M51 may be electrical floating.

Compared with the carrier structure 450-1A/450-2A, the carrier structure 450-1B/450-2B includes a bonding layer 454B is located below the semiconductor carrier 452. More specifically, the bonding layer 454B is disposed on the bottom surface 452B of semiconductor carrier 452. In addition, the bonding layer 454B faces and is directly bonded to the bonding layer 454B of the memory structure 400-1B/400-2B.

In some embodiments, the bonding layers 424B and 454B have the same material and structure. For example, the bonding layer 454B may include metal patterns M52 passing through a dielectric layer D52. The metal patterns M52 may be disposed directly on and completely overlap the corresponding metal patterns M51. In some embodiments, the metal patterns M51 and M52 may have the same dimensions. The dielectric layer D52 may be disposed directly on and completely overlap the dielectric layer D51.

In this embodiment, the carrier structure 450-1B/450-2B is hybrid bonded to the corresponding memory structure 400-1B/400-2B. More specifically, the metal patterns M51 are directly bonded (metal bonded) to the corresponding metal patterns M52. The dielectric layer D51 is directly bonded (fusion bonded) to the dielectric layer D52.

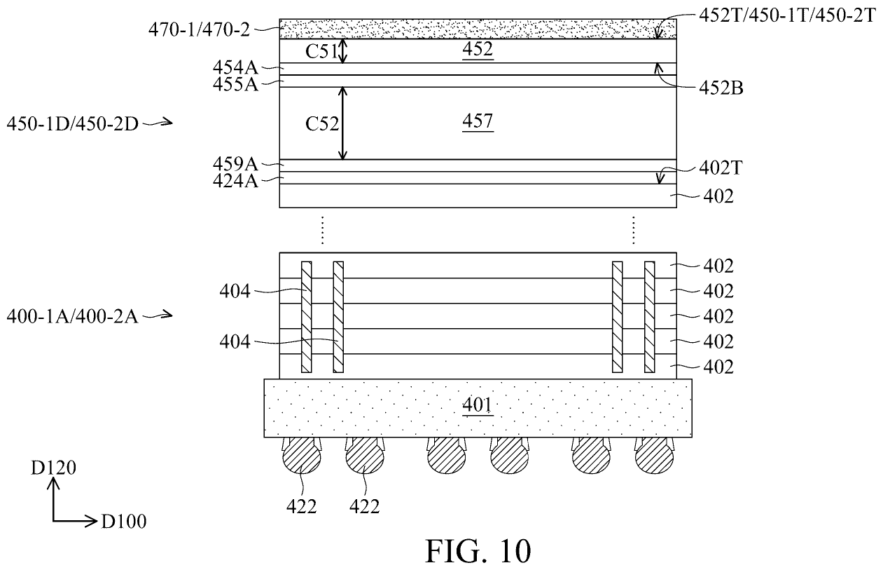

FIG. 10 is a cross-sectional view of a carrier structure 450-1D (or a carrier structure 450-2D) and the memory structure 400-1A (or the memory structure 400-2A) of the semiconductor package assembly 500A (or the semiconductor package assemblies 500B-500D) in accordance with some embodiments of the disclosure. Elements of the embodiments that are the same or similar to those previously described with reference to FIGS. 1, 4A and 8 are not repeated herein, in the interests of brevity. The carrier structure 450-1D/450-2D includes multiple semiconductor carriers and bonding layers on the top and bottom surfaces of each of the semiconductor carriers.

As shown in FIG. 10, compared to the carrier structure 450-1A/450-2A, the carrier structure 450-1D/450-2D may include the semiconductor carrier 452, a semiconductor carrier 457, the bonding layer 454A and bonding layer 455A, 459A. The semiconductor carrier 457 is located between the bonding layer 454A and the bonding layer 424A of the chiplet structure 300-1A/300-2A. In some embodiments, the semiconductor carriers 452, 457 may have the same or similar material and structure. In some embodiments, the height C51 of the semiconductor carrier 452 may be the same as or different from the height C52 of the semiconductor carrier 457 the direction D120.

The bonding layer 455A is disposed between the bonding layer 454A and the second semiconductor carrier 457 of the carrier structure 450-1D/450-2D. In some embodiments, the bonding layer 454A and the bonding layer 455A of the carrier structure 450-1D/450-2D have the same material and structure. For example, when the bonding layers 454A and 455A are dielectric layers formed of the same dielectric material, the bonding layer 454A is fusion bonded to the bonding layer 455A. When the bonding layers 454A and 455A are metal layers formed of the same metal material, the bonding layer 454A is metal bonded to the bonding layer 455A.

The bonding layer 459A disposed between the semiconductor carrier 457 of the carrier structure 450-1D/450-2D and the bonding layer 424A of the memory structure 400-1A/400-2A. In some embodiments, the bonding layer 424A of the memory structure 400-1A/400-2A and the bonding layer 459A of the carrier structure 450-1D/450-2D have the same material and structure. For example, when the bonding layers 459A and 424A are dielectric layers formed of the same dielectric material, the carrier structure 450-1D/450-2D is fusion bonded to the corresponding memory structure 400-1A/400-2A. When the bonding layers 459A and 424A are metal layers formed of the same metal material, the carrier structure 450-1D/450-2D is metal bonded to the corresponding memory structure 400-1A/400-2A.

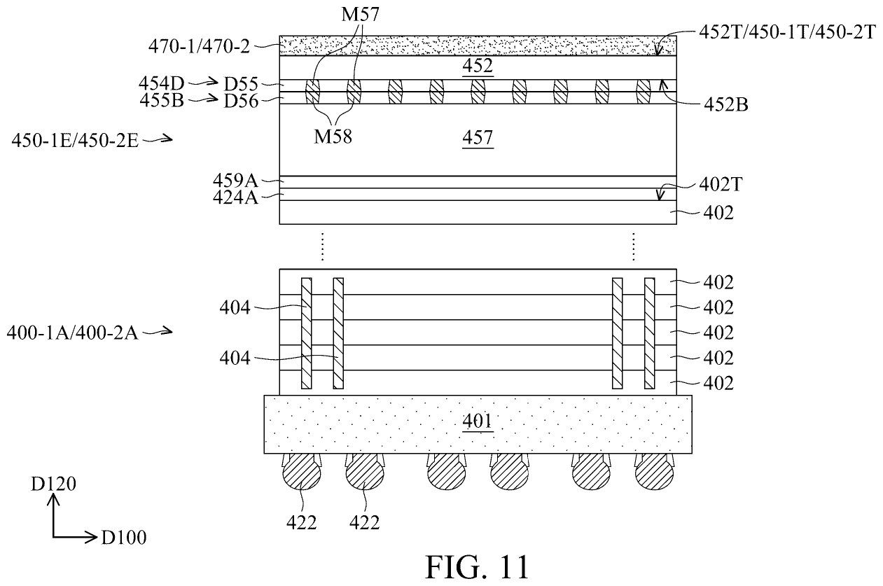

FIG. 11 is a cross-sectional view of a carrier structure 450-1E (or a carrier structure 450-2E) and the memory structure 400-1A (or the memory structure 400-2A) of the semiconductor package assembly 500A (or the semiconductor package assemblies 500B-500D) in accordance with some embodiments of the disclosure. Elements of the embodiments that are the same or similar to those previously described with reference to FIGS. 1, 5A, 8 and 10 are not repeated herein, in the interests of brevity.

Compared with the carrier structure 450-1D/450-2D, the carrier structure 450-1E/450-2E includes the semiconductor carriers 452, 457, the bonding layer 459A, and bonding layers 454D and 455B.

The bonding layer 454D is located below the semiconductor carrier 452. More specifically, the bonding layer 454C is between the semiconductor carrier 452 and the bonding layer 455B. In addition, the bonding layer 454D faces and is directly bonded to the bonding layer 455B of the carrier structure 450-1E/450-2E.

The bonding layer 455B is disposed between the bonding layer 454D and the second semiconductor carrier 457 of the carrier structure 450-1E/450-2E. In this embodiment, the bonding layer 454D and the bonding layer 455B of the carrier structure 450-1E/450-2E have the same material and structure. For example, the bonding layer 454D may include metal patterns M57 passing through a dielectric layer D55. The bonding layer 455B may include metal patterns M58 passing through a dielectric layer D56. The metal patterns M57 may be disposed directly on and completely overlap the corresponding metal patterns M58. In some embodiments, the metal patterns M57 and M58 may have the same dimensions and completely overlap each other. The dielectric layer D55 may be disposed directly on and completely overlap the dielectric layer D56.

In this embodiment, the semiconductor carrier 452 is hybrid bonded to the corresponding the semiconductor carrier 457 via the bonding layers 454D and 455B. More specifically, the metal patterns M57 are directly bonded (metal bonded) to the corresponding metal patterns M58. The dielectric layer D55 is directly bonded (fusion bonded) to the dielectric layer D56.

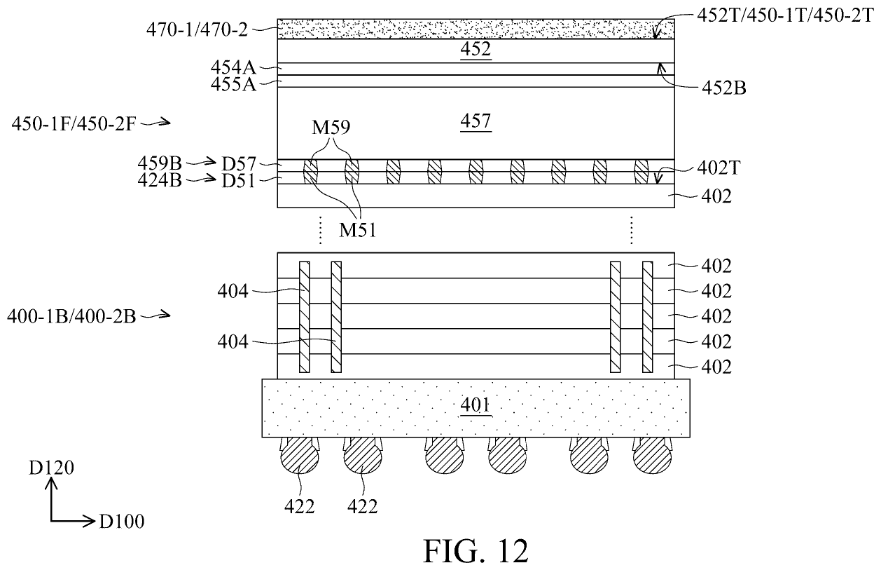

FIG. 12 is a cross-sectional view of a carrier structure 450-1F (or a carrier structure 450-2F) and the memory structure 400-1B (or the memory structure 400-2B) of the semiconductor package assembly 500A (or the semiconductor package assemblies 500B-500D) in accordance with some embodiments of the disclosure. Elements of the embodiments that are the same or similar to those previously described with reference to FIGS. 1, 6A, 9 and 10 are not repeated herein, in the interests of brevity.

Compared with the carrier structure 450-1D/450-2D, the carrier structure 450-1F/450-2F includes the semiconductor carriers 452, 457, the bonding layers 454A and 455A, and a bonding layer 459B. The bonding layer 459B disposed between the semiconductor carrier 457 of the carrier structure 450-1F/450-2F and the bonding layer 424B of the memory structure 400-1B/400-2B. In some embodiments, the bonding layer 424B of the memory structure 400-1A/400-2A and the bonding layer 459B of the carrier structure 450-1F/450-2F have the same material and structure.

For example, the bonding layer 459B may include metal patterns M59 passing through a dielectric layer D57. The metal patterns M59 may be disposed directly on and completely overlap the corresponding metal patterns M51. In some embodiments, the metal patterns M51 and M59 may have the same dimensions. The dielectric layer D57 may be disposed directly on and completely overlap the dielectric layer D51.

In this embodiment, the carrier structure 450-1F/450-2F is hybrid bonded to the corresponding memory structure 400-1B/400-2B. More specifically, the metal patterns M51 are directly bonded to the corresponding metal patterns M59. The dielectric layer D51 is directly bonded to the dielectric layer D57.

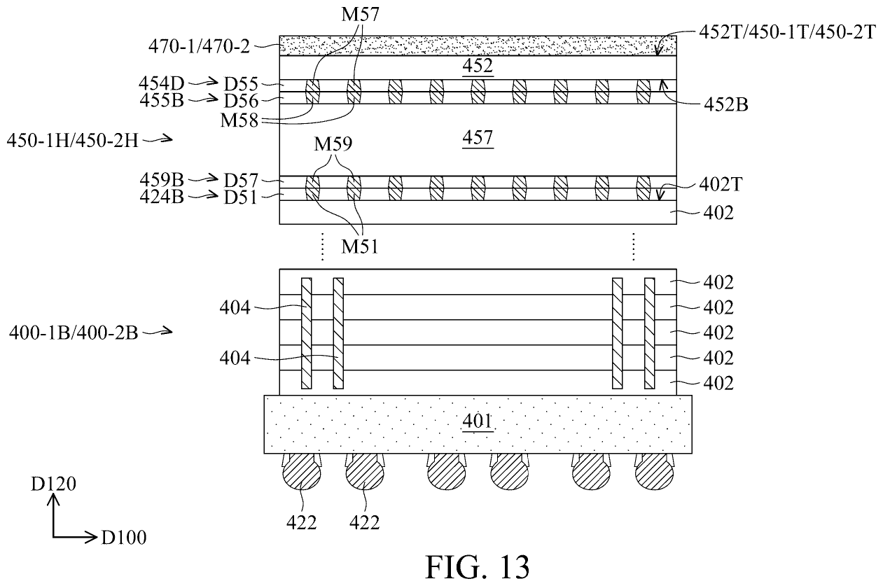

FIG. 13 is a cross-sectional view of a carrier structure 450-1H (or a carrier structure 450-2H) and the memory structure 400-1B (or the memory structure 400-2B) of the semiconductor package assembly 500A (or the semiconductor package assemblies 500B-500D) in accordance with some embodiments of the disclosure. Elements of the embodiments that are the same or similar to those previously described with reference to FIGS. 1, 7A, 11 and 12 are not repeated herein, in the interests of brevity.

Compared with the carrier structure 450-1F/450-2F, the carrier structure 450-1H/450-2H includes the semiconductor carriers 452, 457, and the bonding layers 454D, 455B and 459B.

The bonding layer 454D is located below the semiconductor carrier 452. More specifically, the bonding layer 454D is between the semiconductor carrier 452 and the bonding layer 455B. In addition, the bonding layer 454D faces and is directly bonded to the bonding layer 455B of the carrier structure 450-1H/450-2H.

The bonding layer 455B is disposed between the bonding layer 454D and the second semiconductor carrier 457 of the carrier structure 450-1H/450-2H. In this embodiment, the bonding layer 454D and the bonding layer 455B of the carrier structure 450-1H/450-2H have the same material and structure. For example, the bonding layer 454D may include the metal patterns M57 passing through the dielectric layer D55. The bonding layer 455B may include the metal patterns M58 passing through the dielectric layer D56. The metal patterns M57 may be disposed directly on and completely overlap the corresponding metal patterns M58. In some embodiments, the metal patterns M57 and M58 may have the same dimensions and completely overlap each other. The dielectric layer D55 may be disposed directly on and completely overlap the dielectric layer D56.

In this embodiment, the semiconductor carrier 452 is hybrid bonded to the corresponding the semiconductor carrier 457 via the bonding layers 454D and 455B. More specifically, the metal patterns M57 are directly bonded (metal bonded) to the corresponding metal patterns M58. The dielectric layer D55 is directly bonded (fusion bonded) to the dielectric layer D56.

Embodiments provide a semiconductor package assembly. The semiconductor package assembly uses carrier structures (e.g., the carrier structures 350-1, 350-2, 450-1 and 450-2) directly bonded on the corresponding chiplet structures (e.g., the chiplet structures 300-1, 300-2) and the corresponding memory structures (e.g., the memory structures 400-1, 400-2). Each of the carrier structures include at least one semiconductor carrier and at least one bonding layer. The carrier structures are used to compensate the differences between the heights of the chiplet structures and the memory structures in the vertical direction (e.g., the direction D120). In addition, the thickness of each of the carrier structures is tunable by adjusting the thickness and number of the semiconductor carriers. The total heights of the stack composed of the chiplet structure and the corresponding carrier structure and the stack composed of the memory structure and the corresponding carrier structure may keep the same. In other words, the top surfaces of the carrier structures directly bonded on the chiplet structures (e.g., the chiplet structures 300-1, 300-2) and the memory structures (e.g., the memory structures 400-1, 400-2) are aligned with each other. Therefore, one or more thermal dissipation material layers (e.g., the thermal dissipation layers 370-1, 370-2, 470-1, 470-2, 570, 572 including backside metallization (BSM) layers or thermal interface material (TIM)) may be disposed on the same plane formed by the top surfaces of the carrier structures without defects (e.g., voids) on the interfaces between the thermal dissipation material layers and the chiplet structures and between thermal dissipation material layers and the memory structure. The thermal dissipation material layer may have improved uniformity, and thermal reliability of the semiconductor package assembly can be further improved.

In some embodiment, the semiconductor carrier of the carrier structure can benefit the thermal dissipation efficiency of the chiplet structures and the memory structures. In some embodiment, the carrier structure is directly bonded (including fusion bonded, metal bonded, or hybrid bonded) to the corresponding chiplet structure or memory structure by bonding layers without an air gap between them. The thermal dissipation efficiency of the semiconductor package assembly can be further improved.

Embodiments provide a semiconductor package assembly. The semiconductor package assembly includes a substrate, a first chiplet structure, a memory structure, a first carrier structure, and a second carrier structure. The first chiplet structure is disposed on the substrate. The first chiplet structure has a first height. The memory structure is disposed on the substrate and beside the first chiplet. The memory structure has a second height that is different from the first height in a direction that is substantially perpendicular to a top surface of the substrate. The first carrier structure is bonded to the first chiplet structure. The second carrier structure is bonded to the memory structure and beside the first carrier structure. Top surfaces of the first carrier structure and second carrier structure are aligned with each other.

In some embodiments, the first carrier structure has a third height, the second carrier structure has a fourth height, and the sum of the first height and the third height is equal to the sum of the second height and the fourth height.

In some embodiments, the first chiplet structure includes a first semiconductor die and a redistribution layer (RDL) structure. The redistribution layer (RDL) structure is located below a bottom surface of the first semiconductor die.

In some embodiments, the semiconductor package further including a second semiconductor die disposed on the redistribution layer (RDL) structure and coupled to the first semiconductor die.

In some embodiments, the first semiconductor die overlaps the second semiconductor die.

In some embodiments, the memory structure includes memory dies stacked on each other, and the memory dies are interconnected through first conductive vias.

In some embodiments, the first carrier structure and second carrier structure are fusion bonded, metal bonded, or hybrid bonded to the first chiplet and the memory structure.

In some embodiments, the each of the first carrier structure and the second carrier structure includes a first semiconductor carrier and a first bonding layer. The first bonding layer is located below the first semiconductor carrier.

In some embodiments, the first bonding layer includes a metal layer, a dielectric layer, or a first metal pattern and a second metal pattern passing through a dielectric layer combination thereof.

In some embodiments, the first chiplet structure includes a second bonding layer disposed on a top surface of the first semiconductor die and bonded to the first bonding layer of the first carrier structure. The first and second bonding layers are formed of the same material.

In some embodiments, the memory structure includes a third bonding layer disposed on a top surface of a topmost memory die and bonded to the first bonding layer of the first carrier structure. The first and third bonding layers are formed of the same material.

In some embodiments, the first metal pattern has a first width and the second metal pattern has a second width that is different form the first width in a direction that is substantially parallel to a top surface of the substrate.

In some embodiments, when the first width is wider than the second width, the first metal pattern is disposed directly on the first semiconductor die.

In some embodiments, the semiconductor package assembly further includes thermal dissipation layers disposed on the top surface of the first carrier structure and a top surface of second carrier structure.

In some embodiments, the first carrier structure further includes a second semiconductor carrier, a fourth bonding layer and a fifth bonding layer. The second semiconductor carrier is located between the first bonding layer of the first carrier structure and the second bonding layer of the first chiplet structure. The fourth bonding layer is disposed between the first bonding layer and the second semiconductor carrier of the first carrier structure. The first bonding layer and the fourth bonding layer of the first carrier structure are formed of the same material. The fifth bonding layer is disposed between the second semiconductor carrier of the first carrier structure and the second bonding layer of the first chiplet structure. The second bonding layer and the fifth bonding layer are formed of the same material.

In some embodiments, the fourth bonding layer is bonded to the first bonding layer, and the fifth bonding layer is bonded to the second bonding layer.

In some embodiments, the first semiconductor carrier and the second semiconductor carrier have different heights.

In some embodiments, the second carrier structure further includes a third semiconductor carrier, a sixth bonding layer and a seventh bonding layer. The third semiconductor carrier is located between the first bonding layer of the second carrier structure and the third bonding layer of the memory structure. The sixth bonding layer is disposed between the first bonding layer and the third semiconductor carrier of the second carrier structure. The first bonding layer and the sixth bonding layer of the second carrier structure are formed of the same material. The seventh bonding layer is disposed between the third semiconductor carrier of the second carrier structure and the third bonding layer of the memory structure. The third bonding layer and the seventh bonding layer are formed of the same material.

In some embodiments, the semiconductor package assembly further includes a second chiplet structure and a bridge structure. The second chiplet structure is disposed on the substrate and beside the first chiplet structure. The first chiplet structure has a third height. The bridge structure is embedded in the substrate or in an interposer located between the first chiplet structure and the substrate. The first chiplet structure is coupled to the second chiplet structure through the bridge structure.

In some embodiments, the bridge structure includes a silicon body, an interconnect structure embedded in the silicon body.

Embodiments provide a semiconductor package assembly. The semiconductor package assembly includes a substrate, a first chiplet structure, a memory structure, a first carrier structure, and a second carrier structure. The first chiplet structure is disposed on the substrate. The first chiplet structure has a first height. The memory structure is disposed on the substrate and beside the first chiplet. The memory structure has a second height that is different from the first height in a direction that is substantially perpendicular to a top surface of the substrate. The first carrier structure is bonded to the first chiplet structure. The first carrier structure has a third height. The second carrier structure is bonded to the memory structure and beside the first carrier structure. The second carrier structure has a fourth height. The sum of the first height and the third height is equal to the sum of the second height and the fourth height.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A semiconductor package assembly, comprising:
a substrate;
a first chiplet structure disposed on the substrate, wherein the first chiplet structure has a first height;
a memory structure disposed on the substrate and beside the first chiplet, wherein the memory structure has a second height that is different from the first height in a direction that is substantially perpendicular to a top surface of the substrate;
a first carrier structure bonded to the first chiplet structure; and
a second carrier structure bonded to the memory structure and beside the first carrier structure,
wherein top surfaces of the first carrier structure and second carrier structure are aligned with each other.

2. The semiconductor package assembly as claimed in claim 1, wherein the first carrier structure has a third height, the second carrier structure has a fourth height, and a sum of the first height and the third height is equal to a sum of the second height and the fourth height.

3. The semiconductor package assembly as claimed in claim 1, wherein the first chiplet structure comprises:
a first semiconductor die; and
a redistribution layer (RDL) structure located below a bottom surface of the first semiconductor die.

4. The semiconductor package assembly as claimed in claim 3, further comprising:
a second semiconductor die disposed on the redistribution layer (RDL) structure and coupled to the first semiconductor die.

5. The semiconductor package assembly as claimed in claim 4, wherein the first semiconductor die overlaps the second semiconductor die.

6. The semiconductor package assembly as claimed in claim 3, wherein the memory structure comprises memory dies stacked on each other, and the memory dies are interconnected through first conductive vias.

7. The semiconductor package assembly as claimed in claim 6, wherein the first carrier structure and second carrier structure are fusion bonded, metal bonded, or hybrid bonded to the first chiplet and the memory structure.

8. The semiconductor package assembly as claimed in claim 7, wherein each of the first carrier structure and the second carrier structure comprises:
a first semiconductor carrier; and
a first bonding layer below the first semiconductor carrier.

9. The semiconductor package assembly as claimed in claim 8, wherein the first bonding layer comprises a metal layer, a dielectric layer, or a first metal pattern and a second metal pattern passing through a dielectric layer combination thereof.

10. The semiconductor package assembly as claimed in claim 8, wherein the first chiplet structure comprises a second bonding layer disposed on a top surface of the first semiconductor die and bonded to the first bonding layer of the first carrier structure, wherein the first and second bonding layers are formed of the same material.

11. The semiconductor package assembly as claimed in claim 8, wherein the memory structure comprises a third bonding layer disposed on a top surface of a topmost memory die and bonded to the first bonding layer of the first carrier structure, wherein the first and third bonding layers are formed of the same material.

12. The semiconductor package assembly as claimed in claim 9, wherein the first metal pattern has a first width and the second metal pattern has a second width that is different form the first width in a direction that is substantially parallel to a top surface of the substrate.

13. The semiconductor package assembly as claimed in claim 12, wherein when the first width is wider than the second width, the first metal pattern is disposed directly on the first semiconductor die.

14. The semiconductor package assembly as claimed in claim 1, further comprising:
thermal dissipation layers disposed on the top surface of the first carrier structure and a top surface of second carrier structure.

15. The semiconductor package assembly as claimed in claim 10, wherein the first carrier structure further comprises:
a second semiconductor carrier between the first bonding layer of the first carrier structure and the second bonding layer of the first chiplet structure;
a fourth bonding layer disposed between the first bonding layer and the second semiconductor carrier of the first carrier structure, wherein the first bonding layer and the fourth bonding layer of the first carrier structure are formed of the same material; and
a fifth bonding layer disposed between the second semiconductor carrier of the first carrier structure and the second bonding layer of the first chiplet structure, wherein the second bonding layer and the fifth bonding layer are formed of the same material.

16. The semiconductor package assembly as claimed in claim 15, wherein the fourth bonding layer is bonded to the first bonding layer, and the fifth bonding layer is bonded to the second bonding layer.

17. The semiconductor package assembly as claimed in claim 15, wherein the first and second semiconductor carriers have different heights.

18. The semiconductor package assembly as claimed in claim 11, wherein the second carrier structure further comprises:
a third semiconductor carrier between the first bonding layer of the second carrier structure and the third bonding layer of the memory structure;
a sixth bonding layer disposed between the first bonding layer and the third semiconductor carrier of the second carrier structure, wherein the first bonding layer and the sixth bonding layer of the second carrier structure are formed of the same material; and
a seventh bonding layer disposed between the third semiconductor carrier of the second carrier structure and the third bonding layer of the memory structure, wherein the third bonding layer and the seventh bonding layer are formed of the same material.

19. The semiconductor package assembly as claimed in claim 1, further comprising:
a second chiplet structure disposed on the substrate and beside the first chiplet structure, wherein the first chiplet structure has a third height; and
a bridge structure embedded in the substrate or in an interposer located between the first chiplet structure and the substrate, wherein the first chiplet structure is coupled to the second chiplet structure through the bridge structure.

20. A semiconductor package assembly, comprising:
a substrate;
a first chiplet structure disposed on the substrate, wherein the first chiplet structure has a first height;
a memory structure disposed on the substrate and beside the first chiplet, wherein the memory structure has a second height that is different from the first height in a direction that is substantially perpendicular to a top surface of the substrate;
a first carrier structure bonded to the first chiplet structure, wherein the first carrier structure has a third height; and
a second carrier structure bonded to the memory structure and beside the first carrier structure, wherein the second carrier structure has a fourth height, and
wherein a sum of the first height and the third height is equal to a sum of the second height and the fourth height.
